(19) United States
(12) Patent Application Publication
(10) Pub. No.: US 2020/0262746 A1
(43) Pub. Date: Aug. 20, 2020

(54) PROTECTIVE COVER, ITS USE AND METHOD OF MAKING A PROTECTIVE COVER

(71) Applicant: SCHOTT GLASS TECHNOLOGIES (SUZHOU) CO. LTD., Jiangsu (CN)

(72) Inventors: Feng HE, Jiangsu (CN); Ning DA, Jiangsu (CN); Jose ZIMMER, Eppstein (DE); Matthias JOTZ, Mainz (DE)

(21) Appl. No.: 16/868,172

(22) Filed: May 6, 2020

Related U.S. Application Data
(63) Continuation of application No. PCT/CN2018/085283, filed on May 2, 2018.

(51) Int. Cl. C03C 17/34; H01L 51/00; H01L 51/52

(52) U.S. Cl. CPC C03C 17/3405; H01L 51/0097; C03C 2217/78; H01L 2251/5338; H01L 51/524

(57) ABSTRACT

The present disclosure relates to a protective cover including at least one transparent inorganic layer and at least one transparent adhesion layer. The transparent inorganic layer may include glass or glass ceramic. In a preferred embodiment, the inorganic layer is glass or glass ceramic. In an embodiment, the protective cover further includes a polymer layer disposed between the inorganic layer and the adhesion layer.

### CROSS-REFERENCE TO RELATED APPLICATIONS

The present application is a continuation of International Patent Application PCT/CN2018/085283, filed on May 2, 2018, which in turn claims the benefit of International Patent Application PCT/CN2017/000708, filed on Nov. 6, 2017, each of which is incorporated by reference.

### BACKGROUND OF THE DISCLOSURE

### 1. Field of the Disclosure

The present application relates to a protective cover, a method of making the protective cover, and methods of using the protective cover. The protective cover of this invention may be arranged on a display of an electronic device, or the protective cover may be an integral part of the display, or the protective cover may itself constitute the display of an electronic device. The electronic device may be a device having an LCD or OLED display. The electronic device may be a smartphone, tablet PC, laptop computer, smart bracelet, or any other handheld and/or portable electronic device

### 2. Background of the Related Art

A new generation of electronic displays e.g. for mobile devices will be foldable or rollable. Surfaces of these displays will be made of thin polymers like PI (polyimide) or ultrathin glasses. The devices additionally need to be able to be folded or rolled e.g. more than 100,000 times in a typical product lifetime without any damage. Scratch and breakage resistance are critical for the device. Also impact resistance (e.g. pen drop, or other sharp impact) are critical and should not lead to damage of the surface or the electronic functionalities of the display or a touch sensor.

There is an increasing demand in the marketplace for curved, bendable and foldable electronic devices such as smartphones and tablet PCs, or other electronic devices with displays. Such devices are described for example in US 2017/0294495 A1, which is incorporated herein by reference in its entirety. Many manufacturers use polymeric display cover materials, such as polyimide, PET or other polyesters, polycarbonate, acrylic polymers or other polymers. Polymeric display cover materials have the advantage of being inherently elastic, bendable or even foldable when used at sufficiently low thicknesses. On the other hand, these materials are less resistant to scratches, light irradiation, cleaning agents, temperature and overall wear and tear.

There are many inorganic materials that are resistant to scratches and irradiation, and which easily withstand use of cleaning agents. However, most of these materials are usable as covers for curved surfaces, but not for bendable or even foldable devices. Furthermore, many of these materials are very brittle. Particularly, glass has been used as cover material for displays for many years.

It is expected that very soon mobile phone manufacturers will offer a truly foldable mobile phone, for example a phone with a display almost completely covering one side of the phone and being foldable and having a bending axis which may be oriented perpendicularly to the display's longitudinal axis, dividing the display into essentially equal parts. In other words, such an electronic device opens and closes like a book.

Prior art disclosures such as WO 2017/123899 A1 rely on foldable cover assemblies that comprise foldable glass layers and polymeric layers as outer layers, i.e. the surface facing away from the electronic device is covered with a polymeric layer in order for the cover assembly to withstand a pen drop. Other disclosures like WO 2017/136507 A1 rely on outer layers of glass having indentations on the outer surface of a cover glass.

It would be useful to have a protective cover that imparts the display with the beneficial properties of a resistant inorganic material, while maintaining the bendable or even foldable characteristics of the display device, and which does not significantly impair any touch screen functions of the device, such as capacitive touch sensor components, resistive touch sensor components, acoustic touch sensor components, force based touch sensor components, or light-based touch sensor components.

### SUMMARY OF THE DISCLOSURE

The present disclosure relates to a protective cover that overcomes the drawbacks of the prior art by presenting an article that has an inorganic material layer as its outer surface. The protective cover of this invention comprises at least one transparent inorganic material layer, and at least one transparent adhesion layer. The thickness of the protective cover may be less than 500 μm, less than 250 μm or less than 150 μm.

The inorganic material layer can be used to cover the display of a bendable and/or foldable electronic device, to be an integral part of the display of a bendable and/or foldable electronic device, or to constitute the display of a bendable and/or foldable electronic device. The present inventors have identified a number of measures that make the inorganic material strong enough to withstand the strains and stresses that are imparted on the protective cover during use of the electronic device that it protects. To solve the issues of the prior art mentioned above, a bendable glassy protection film (protective cover) which is removable can be applied to the surface of the device, or be an integral part of the surface of the device, or constitute the surface of the device. The glass film is able to fulfill the folding requirements of the device and protects the original surface from impact and scratches.

The protective cover of this disclosure can in one embodiment be regarded as a glass film glued to the original polymer or glass surface of the device with an adhesion layer in a non-permanent (removable) way. The adhesion layer can be a single or multilayer adhesives (e.g. silicones, PSA etc.). Consequently, in an embodiment, the adhesion layer can form one of the outer layers of the protective cover.

The possible bending radius of the protective cover can be smaller than 50 mm, smaller than 20 mm, smaller than 15 mm, smaller than 10 mm, or smaller than 7 mm.

The adhesion layer, and/or an optional further polymer layer, can also be used for splinter protection. Substantially no glass splinters should be released from the surface of the protective cover in case of breakage but should stick to the surface to avoid any harm to the user of the device, or any other person or material in its surroundings, such as any other parts of the device. In an embodiment, in case of breakage or defective appearance of the surface the protective cover can be removed and replaced by a new cover.

Polymer covers have the disadvantage of high scratch and chemical sensitivity. Also the haptic experience of polymers to consumers is inferior to glass surfaces.

The adhesion layer should support easy and bubble free application to the protective cover and support easy removal in case exchange of the film is necessary.

The transparent inorganic material layer can comprise glass or glass ceramic. In a preferred embodiment, the inorganic material layer consists of glass or glass ceramic. In an embodiment, the protective cover further comprises a polymer layer disposed between inorganic material layer and adhesion layer.

In preferred embodiments, the inorganic material layer is an outer layer, i.e. the inorganic material layer is in contact with the surrounding atmosphere, such as air. The adhesion layer on the other hand can be determined to provide for proper adhesion of the protective cover to a display of an electronic device, such as a polyimide display, or it may provide adhesion of the inorganic material layer to any other layer of the protective cover, such as an additional inorganic material layer. Dimensions and type of the adhesion layer can be chosen to provide for good adhesive strength, but also the ability to be removed again from the protected display, e.g. by peeling off the protective cover.

A polymer layer can be arranged between inorganic material layer and adhesion layer. The polymer layer can increase mechanical stability of the protective cover. It can also provide security to the user of the protective cover by securing particles of a broken inorganic material layer by holding these particles together. The polymer layer can also protect the display, in case of breakage of the inorganic material by keeping the particles of the inorganic material fixed to the polymer layer.

The protective cover can be infoldable and/or outfoldable, i.e. the protective cover can be folded so that the inorganic layer is on the inside of the folded protective cover, or on the outside of the folded protective cover.

The inorganic material of the inorganic material layer may be toughened or untoughened, chemically toughened or not chemically toughened, or partially toughened.

In one embodiment, the present disclosure provides a protective cover comprising at least one transparent inorganic material layer and at least one transparent adhesion layer. The coefficient of thermal expansion of the inorganic material layer is from 1 to 10 ppm/K. The thickness of the inorganic material layer is less than 250 μm. The thickness of the adhesion layer is less than 100 μm. The inorganic material layer comprises a glass or a glass ceramic, or consists of a glass or a glass ceramic. The protective cover is bendable and/or foldable and has a bending axis that is perpendicular to a longitudinal axis of the inorganic material layer. The protective cover has a weight loss after breakage of less than 10%.

The following definitions apply to terms used in the present disclosure.

Thickness (t or d): The thickness, such as the thickness of a layer, is the arithmetic average of the thickness of the layer to be measured.

Compressive Stress (CS): The induced compression of the glass network after ion-exchange on the surface layer of glass. Such compression is not released by deformation of glass and sustained as stress. CS decreases from a maximum value at the surface of the glass article (surface CS) towards the inside of the glass article. Commercially available test machines such as FSM6000 (company “Luceo Co., Ltd.”, Japan/Tokyo) can be used to measure the CS by wave guide mechanism or by SLP1000 (company “ORIHARA”, Japan), which measure the CS by scattered light mechanism.

Depth of Layer (DoL): The thickness of an ion-exchanged layer, i.e. a region where CS exists. Commercially available test machines such as FSM6000 (company “Luceo Co., Ltd.”, Japan/Tokyo) can be used to measure the DoL by wave guide mechanism. Central Tension (CT): When CS is induced on one side or both sides of a glass sheet, to balance the stress according to the 3^{rd} principle of Newton's law, a tension stress must be induced in the center region of glass, and it is called central tension. CT can be calculated from measured CS and DoL.

Average roughness (Rₐ): A measure of the texture of a surface. It is quantified by the vertical deviations of a real surface from its ideal form. Commonly amplitude parameters characterize the surface based on the vertical deviations of the roughness profile from the mean line. Rₐ is the arithmetic average of the absolute values of these vertical deviations.

Breakage force: The breakage force is the force (given in N) that can be applied by an object until an article breaks (that means: cracks are generated). The breakage force is determined by a steel rod sandpaper pressing test which is described in more detail below.

Breakage height: The breakage height is the height (given in mm) from which an object of a defined weight can fall onto an article or layer before the article or layer breaks (that means: cracks are generated). The breakage height is determined by sandpaper ball drop test which is described in more detail below.

Breakage bending radius (BBR): The breakage bending radius (given in mm) is the minimum radius (r) of the arc at the bending position where an article, such as a layer, reaches the maximum deflection before kinking or damaging or breaking. It is measured at the inside curvature at the bending position of an article. A smaller radius means greater flexibility and deflection of the article. The bending radius is a parameter depending on the thickness of the article, the Young's modulus and the material strength. For example, ultrathin glass or glass ceramic may have very small thickness, low Young's modulus and high strength. All the three factors contribute to low bending radius and better flexibility. The test for determining the BBR is described in more detail below. Transparent: a substance, composition, article or layer is considered transparent, if the internal transmittance for electromagnetic radiation is more than 25%, more than 50%, more than 70%, more than 80%, more than 90%, more than 95% or more than 99% at a thickness of 2 mm at wavelengths of 400 nm and/or 700 nm, or in a wavelength range of 50 nm within a spectrum of from 380 to 800 nm.

### BRIEF DESCRIPTION OF THE DRAWINGS

FIG. 1 shows an ultra-thin glass (UTG) that can be used as inorganic layer in the protective cover of this disclosure.

FIG. 2 shows a protective cover in accordance with a preferred embodiment of the disclosure.

FIG. 3 illustrates the bending behavior of an inorganic layer without any further layers.

FIG. 4 illustrates the bending behavior of an inorganic layer with an adhesion layer.

FIG. 5 shows the test setup for performing the pen drop test for an unbent protective cover.

FIG. 6 shows the test setup for performing the pen drop test for a bent protective cover.

FIG. 7 shows an example of an inorganic material layer with areas of reduced thickness.

FIG. 8 shows an example of an inorganic material layer with an area of reduced thickness.

### DETAILED DESCRIPTION OF THE DISCLOSURE

Referring to the drawings, FIG. 1 shows a layer of ultra-thin glass that can be used as inorganic layer 2, including a neutral plane 5. By definition, the neutral plane is a plane within the protective cover that has the same length after bending as before bending. In preferred embodiments, the neutral plane is positioned within the inorganic layer, the polymer layer, and/or the adhesion layer. In preferred embodiments, the neutral plane is positioned in the direction of the adhesion layer with regard to a middle plane of the inorganic layer. The inorganic layer 2 in this figure is shown in an unbent state.

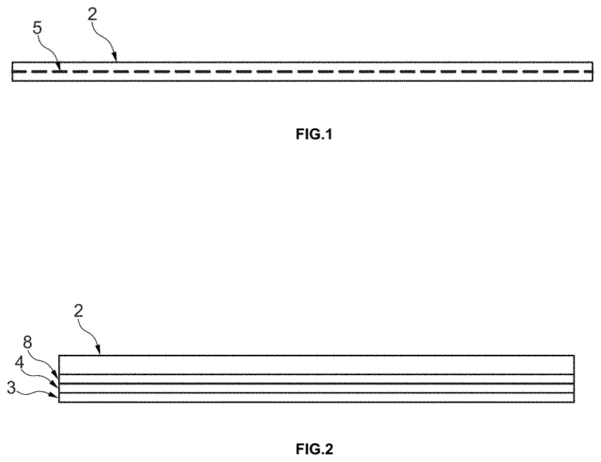

FIG. 2 shows a protective cover 1 in accordance with a preferred embodiment of the invention. The protective cover 1 has an inorganic layer 2 which may be a glass layer. An optional polymer layer 4 such as a polyethylene layer may be attached to the inorganic layer 2 using an optically clear adhesive (OCA) layer 8. A further adhesion layer 3 can be formed using silicone which is suitable for removably attaching the protective cover 1 to an electronic device such as a smartphone. In a preferred embodiment, the overall thickness of OCA layer 8, polymer layer 4 and adhesion layer 3 add up to about 0.1 mm, preferably from 75 to 125 μm.

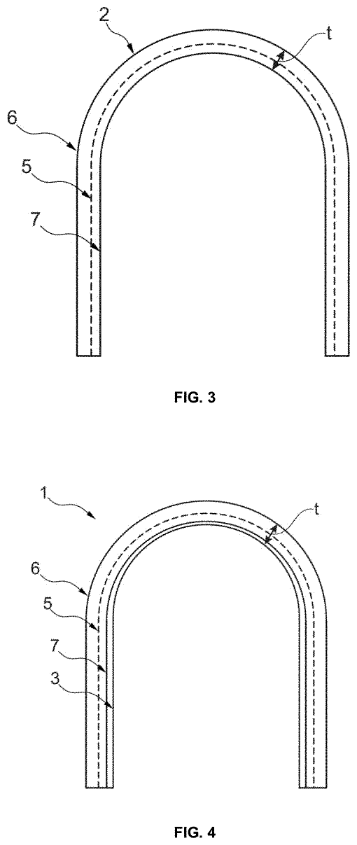

FIG. 3 shows an inorganic layer 2 being bent. The layer has a thickness t. The outer surface is the tension surface 6, which is elongated due to the tension stress. The inner surface is the compression surface 7, which is shortened due to compression. The neutral plane 5 is shifted towards the compression surface 7.

FIG. 4 shows a similar situation as FIG. 3, in which the neutral plane is shifted even more when an adhesion layer 3 is present on the inorganic layer 2. The neutral plane should not move out of the compression surface 7 of the inorganic material layer 2 because if it did, a compressive force would be exerted on the inorganic layer 2, which might have negative consequences such as an external force on the cover glass and display. Therefore, the strain of the tension surface 6 may be less than 4% by calculating the curve area as shown in FIGS. 3 and 4.

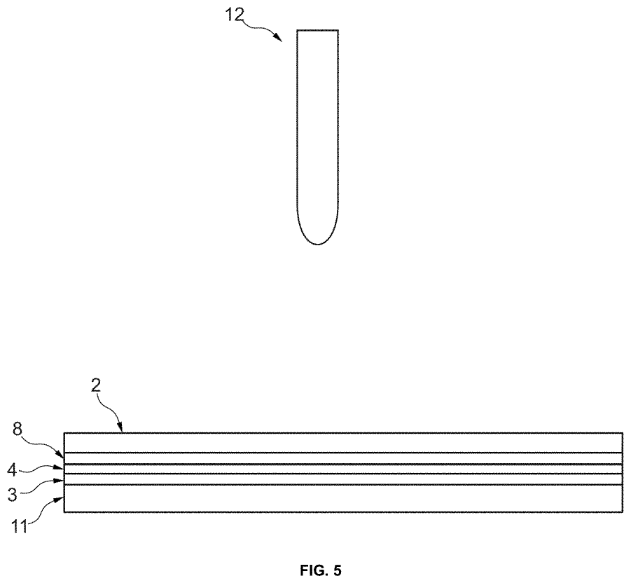

FIG. 5 shows the pen drop set up for unbent protective covers. A protective cover includes an inorganic layer 2 and an adhesion layer 3. The adhesion layer 3 is indirectly attached to the inorganic layer 2 by intermediate layers, namely an additional adhesion layer in the form of OCA layer 8, and a polymer layer 4. The adhesion layer 3 is attached to a steel plate 11. A ball-point pen drop is performed. To simplify the results, a 0.5 mm thick steel plate 11 is replaced as the flexible smartphone. The weight of the ball-point pen is around 5 g. The ball of the pen 12 made of tungsten carbide has a radius of 0.35 mm. The pen drop starts from a height of 10 mm. The height is increased until the protective cover breaks. The greatest height at which the inorganic layer 2 does not break after pen drop is the pen drop height. 30 pieces of the protective cover are tested and the average pen drop height is recorded.

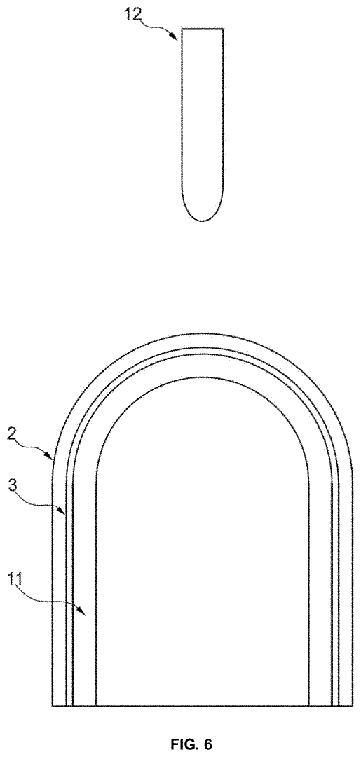

FIG. 6 shows the pen drop set up for curved or bent protective covers. A protective cover includes an inorganic layer 2 and an adhesion layer 3. The adhesion layer 3 is fixed to the inorganic layer 2. The adhesion layer 3 is attached or connected? to a steel plate 11. A ball-point pen drop is performed. To simplify the results, a 0.5 mm thick steel plate 11 is replaced as the flexible smartphone. The weight of the ball-point pen is around 5 g. The ball of the pen 12 made of tungsten carbide has a radius of 0.35 mm. The bending radius is 4 mm. The pen drop starts from a height of 5 mm. The height is increased until the protective cover breaks. The greatest height at which the inorganic layer 2 does not break after pen drop is the pen drop height. 30 pieces of the protective cover are tested and the average pen drop height is recorded.

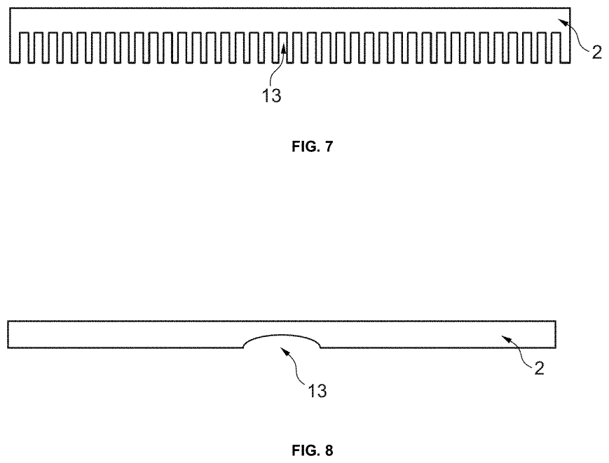

FIG. 7 shows an inorganic material layer 2 that can be used as an additional inorganic material layer in embodiments of this invention, such as a second inorganic material layer, or a first inorganic material layer. The following description of the figure is not limited to the specific embodiment shown, but may apply to all embodiments of this invention with one or more areas of reduced thickness. The inorganic material layer 2 may also be used as the only inorganic material layer in protective covers that have exactly one inorganic material layer. The inorganic material layer 2 has a plurality of areas of reduced thickness 13 in the form of grooves or furrows. These areas provide flexibility to the inorganic material layer. The areas of reduced thickness can be disposed on the side facing towards the electronic device and/or an adhesion layer so as to preserve the smooth surface of the inorganic material layer at a layer/air interface. The areas of reduced thickness can optionally be filled with an elastic material such as a polymer material, e.g. an epoxy resin—or any other material described above for a polymer layer, so as to preserve the impact resistance of the inorganic material layer and/or to maintain good optical appearance. The filling material may have a similar refractive index n_{d} as the inorganic material, such as a refractive index that differs from the refractive index of the inorganic material by not more than 0.3, or not more than 0.2, or not more than 0.1. Keeping the refractive index in that range will improve the optical appearance of the protective cover. An adhesion layer can cover the areas of reduced thickness to facilitate attachment of the inorganic material layer to any further layer or a display or an electronic device. The areas of reduced thickness may provide excellent flexibility and/or bendability.

In an alternative embodiment, the grooves or furrows extend all the way through of the first and/or second inorganic material layer in the thickness direction, thereby forming gaps in the respective layer.

FIG. 8 shows another example of first or second inorganic material layer 2 with an area of reduced thickness 13. The following description of the figure is not limited to the specific embodiment shown, but may apply to all embodiments of this disclosure with one or more areas of reduced thickness. The inorganic material layer 2 may also be used as the only inorganic material layer in protective covers that have exactly one inorganic material layer. The lowest thickness may be substantially where the bending axis is. In this case the area of reduced thickness can be prepared by etching. The etched part can have a rectangular shape or other concave shape. The area of reduced thickness may be arc-shaped as shown in the figure. Arc-shaped areas of reduced thickness are less susceptible to breakage compared to rectangular areas of reduced thickness. In embodiments, an arc-shaped area of reduced thickness has a cross-sectional shape along a cutting plane perpendicular to the bending axis of the inorganic material layer, which has the approximate shape of a semi-circle, wherein “semi-circle” includes circular segments of from 10%, or from 20% or from 30% or from 40% to about 60% of the periphery of the respective circle. In an embodiment, “semi-circle” relates to a circular segment of about 50% of the periphery of the respective circle. In other embodiments, the arc-shaped area of reduced thickness has a cross-sectional shape along a cutting plane perpendicular to the bending axis of the inorganic material layer, which has the approximate shape of a semi-ellipse, wherein “semi-ellipse” includes segments of from 10%, or from 20% or from 30% or from 40% to about 60% of the periphery of the respective ellipse. In an embodiment, “semi-ellipse” relates to a segment of about 50% of the periphery of the respective ellipse. The ellipse has a semi-major axis and a semi-minor axis. In an embodiment, the semi-minor axis is oriented in the thickness direction of the inorganic material layer and the semi-major axis is oriented parallel to the surface of the inorganic material layer. In an alternative embodiment, the semi-major axis is oriented in the thickness direction of the inorganic material layer and the semi-minor axis is oriented parallel to the surface of the inorganic material layer. The semi-major axis can have a length of at least 1.1*mi, or at least 1.3*mi, or at least 1.5*mi, or at least 1.8*mi, or even at least 2*mi or at least 3*mi, wherein mi is the length of the semi-minor axis of the ellipse.

The following are some illustrative and preferred embodiments of this invention, wherein the sequence of characters from left to right illustrates a sequence of layers in the protective cover from top to bottom, in the direction of the protected device. “11” indicates the at least one inorganic material layer, “A” indicates adhesion layer, “P” indicates polymer layer, and “12” indicates a second inorganic material layer. The illustrative embodiments A to G may comprise the indicated layers, or they may consist of these layers.

| Type | 1^{st} layer | 2^{nd} layer | 3^{rd} layer | 4^{th} layer |
|---|---|---|---|---|
| A | I1 | A | | |
| B | I1 | P | A | |
| C | I1 | P | A | I2 |
| D | I1 | P | I2 | |
| E | I1 | A | I2 | |
| F | I1 | P | I2 | A |
| G | I1 | A | I2 | A |
| H | I1 | A | P | A |

In an embodiment, the first inorganic material layer, the adhesion layer, the polymer layer, and/or any additional inorganic material, or all of the layers of the protective cover are transparent. The difference in refractive index n_{d} between any of the layer may be limited to 0.3, or 0.1. The different layers in the above-mentioned sequence of layers of the protective cover may be adjacent each other, and/or in direct contact with each other, i.e. without any additional layers in between. In an embodiment, at least one, some or all of the layers are coextensive, i.e. have the same width and length so that each layer covers its adjacent layer(s) substantially completely. When used, the first inorganic material layer 11 is the outer layer, i.e. facing away from the electronic device and/or towards its user. In embodiments, more than one adhesive layer may be used, e.g. an adhesive layer may be used on each side of a polymer layer to attach the polymer layer to a display and/or to adjacent layers such as inorganic material layers. The polymer layers may be polyethylene layers.

In an embodiment, the disclosure comprises a protective cover, wherein the difference in refractive index nd of inorganic material layer and adhesion layer and/or polymer layer and/or additional inorganic material layer is less than 0.3, preferably less than 0.2 or less than 0.1. Limiting the differences between the indexes of refraction allows for decreased reflection losses in the protective cover when used on a display so that reduced power consumption is achieved, leading to longer battery life in mobile devices.

In an embodiment, the coefficient of thermal expansion (20 to 300° C.) of the inorganic material layer is from 1 to 20 ppm/K, in particular less than 18 ppm/K, less than 16 ppm/K or less than 14 ppm/K. In an embodiment the coefficient of thermal expansion (20 to 300° C.) of the polymer layer is at least 1 ppm/K, preferably from 4 to 30 ppm/K. Preferably, the differences in CTE between adjacent layers, such as between inorganic material layer and polymer layer, and/or between inorganic material layer and adhesion layer, and/or between adhesion layer and additional inorganic material layer, and/or between polymer layer and additional inorganic material layer, are low, particularly less than 40 ppm/K, less than 30 ppm/K, less than 25 ppm/K or even less than 20 ppm/K. Similar CTEs prevent the layers from delamination and increase product lifetime.

The protective cover of this disclosure may exhibit a weight loss after breakage of less than 10%, or less than 5% or less than 2% or less than 1% of the inorganic material. The weight loss, which is defined by comparing the weight difference of broken and unbroken protective covers, can be measured through a precision balance with accuracy of 0.01 g. The particle sizes after breakage are in the size range of from 0.01 to 10 mm, preferably less than 5 mm, less than 3 mm, less than 2 mm, less than 1 mm or less than 0.5 mm. The particle sizes may be measured using microscopy. The diameter may be the Martin diameter.

The protective cover of this disclosure is preferably bendable and/or foldable. It may have a bending axis which may be arranged perpendicularly to the longitudinal axis of the inorganic material layer and/or the protective cover. The bending axis may be substantially perpendicular to the longitudinal axis, or substantially parallel to the longitudinal axis, depending on how the protective cover is supposed to be bent or folded. The bending axis extends at the surface of the inorganic material layer, where the tensile stress peaks during bending. The protective cover of this disclosure is preferably bendable and/or foldable and has a bending axis which may be arranged perpendicularly to the longitudinal axis of the inorganic material layer, wherein the protective cover withstands at least 100,000 bending and/or folding events without breakage. The protective cover of this disclosure is preferably bendable and/or foldable and has a bending axis which may be arranged perpendicularly to the longitudinal axis of the inorganic material layer, wherein the protective cover withstands at least 200,000 bending and/or folding events without breakage. A bending and/or folding event may be effected by bending and/or folding a protective cover from an unbent state to a bent state and back to an unbent state having a bending radius of 50 mm or less, or 20 mm or less, or 10 mm or less, or 5 mm or less, or 2 mm or less. The bending radius may be at least 1 mm.

In a preferred embodiment, the cover is arranged on the display of an electronic device, or forms an integral part of such a display, or constitutes the display. Arranging the cover on a display may be achieved by simply putting the cover on the display and smoothening down the cover with the fingers.

The disclosure also relates to a method of using a protective cover for protecting a display, such as an industrial or consumer display, in particular a smartphone display, in particular a polymeric smartphone display, in particular a polyimide display, in particular a foldable display, in particular an OLED display, comprising the step of applying the protective cover to the display.

In preferred embodiments, the adhesion layer, the polymer layer, and/or any further layers of the protective cover can compensate for the restoring force of the inorganic material layer upon being bent or folded. In preferred embodiments, the adhesion layer is not subjected to tensile stress.

### Inorganic Material Layer

The following features described with regard to the inorganic material layer may characterize at least one inorganic material layer and/or any additional inorganic material layer of the protective cover.

The inorganic material layer can be a glass layer, a glass ceramic layer, ceramic layer or crystal layer. In preferred embodiments, the inorganic material layer is a glass layer or a glass ceramic layer. The inorganic material layer can be additionally coated for e.g. anti-reflection, anti-scratch, anti-fingerprint, anti-microbial, anti-glare and combinations of these functions; such coatings may be arranged on the side facing away from the display to be protected, i.e. facing away from an adhesion layer. The protective cover may comprise more than one inorganic material layer. The inorganic material layer can have surface nitridation to increase its surface resistance.

The thickness of the inorganic material layer can be less than 700 μm, less than 500 μm, less than 300 μm, less than 250 μm, less than 200 μm, less than 150 μm, less than 100 μm, less than 75 μm, less than 70 μm, less than 50 μm, less than 30 μm, or less than 15 μm. The thicker the glass is, the higher is the mechanical stability. The thinner the glass is, the higher is its ability to bend and fold.

The inorganic material layer can have a Vickers hardness HV_{0.2/25} of from 400 to 800 MPa. A toughened inorganic layer may have a Vickers hardness HV_{0.2/25} of from 450 to 1000 MPa. An untoughened inorganic layer may have a Knoop hardness HK_{0.1/20} of from 350 to 750 MPa. A toughened inorganic layer may have a Knoop hardness HK_{0.1/20} of from 400 to 800 MPa.

In certain embodiments, the inorganic material layer, which may be a glass or glass ceramic layer, may have a thickness of less than 0.2 mm, less than 0.175 mm, less than 0.145 mm, less than 0.1 mm, less than 0.1 mm, less than 0.07 mm, or even less than 0.05 mm.

### Pen Drop Height

In certain embodiments, the inorganic material layer has a scratch resistance larger than 6H and/or a pen drop height larger than 30 mm, in particular for thicknesses of at least 0.07 mm. The weight of the pen is around 5 g and the tip of the pen is made of tungsten carbide with a radius of 150 μm. In certain embodiments, the inorganic material layer exhibits a pen drop height in the unbent state of at least 50 mm, at least 60 mm, at least 70 mm, at least 80 mm, at least 90 mm, or at least 100 mm, or at least 120 mm, or at least 150 mm. The pen drop height of the inorganic material, particularly of the inorganic material in the protective cover, is preferred to be larger than 40 mm when the inorganic material is unbent.

The pen drop height of the inorganic material, particularly of the inorganic material in the protective cover, may be at least 20 mm when the bending radius of the inorganic material is larger than 6 mm, and in particular when the bending radius of the inorganic material is up to 10 mm or up to 8 mm. The pen drop height is preferred to be at least 15 mm when the bending radius of the inorganic material is larger than 4 mm and in particular when the bending radius of the inorganic material is up to 8 mm or up to 6 mm. The pen drop height is preferred to be larger than 10 mm when the bending radius of the inorganic material is larger than 2 mm and in particular when the bending radius of the inorganic material is up to 6 mm or up to 4 mm.

It is desirable that the protective cover has a ratio of the pen drop height in the bent state; when the bending radius of the inorganic material is larger than 4 mm, and in particular when the bending radius of the inorganic material is up to 8 mm or up to 6 mm; to the pen drop height in the unbent state of not less than 30%, not less than 25%, or not less than 20%. The measurement of the pen drop test is illustrated in FIGS. 5 and 6. In preferred embodiments, the protective cover is foldable at least 100.000 times, in particular at least 200.000 times without breakage. This may apply to a bending radius of 20 mm or less. Further, it may apply to infoldable and/or outfoldable displays and/or protective covers.

The inorganic material may be glass which contains alkali metal oxides so that it can be chemically toughened. For inorganic material of toughened glass the CS (compressive stress) may be in the range of 200 to 2000 MPa and/or the DoL (depth of layer) may be in the range of 2 μm<DoL<half of thickness of inorganic material layer.

### Bending Strength

The bending strength can be measured using the 2PB method and the average bending strength of the inorganic material layer and/or the protective cover may be larger than 850 MPa, preferably more than 900 MPa, even more preferably more than 950 MPa, even more preferably more than 1000 MPa. The foldability is measured by the bending radius, which may be less than 20 mm, less than 10 mm, less than 7 mm, less than 5 mm, or even less than 4 mm. In an embodiment, the bending radius may be at least 1 mm, or at least 2 mm, or at least 3 mm.

The hardness of the inorganic material may be as follows: HV_{0.2/25}>400 MPa, and/or HK_{0.1/20}>350 MPa. After toughening the values may be HV_{0.2/25}>450 MPa, and/or HK_{0.1/20}>400 MPa. After toughening with surface nitridation the values may be HV_{0.2/25}>500 MPa, and/or HK_{0.1/20}>450 MPa.

The Young's modulus may be larger than 50 GPa, larger than 55 GPa, or larger than 60 GPa. The Young's modulus may be less than 110 GPa, less than 105 GPa, or less than 100 GPa.

In preferred embodiments, the optical transmittance of the inorganic material is larger than 85% @400 nm and/or larger than 88% @700 nm.

### Alkali Leaching Factor

The inorganic material of the present disclosure can have an alkali leaching factor of at most 20 μmol/dm², at most 10 μmol/dm², at most 5 μmol/dm², or even at most 3 μmol/dm². For determining the alkali leaching factor, a material sample is first washed in deionized water for 8 minutes at 80° C. and subsequently rinsed with deionized water at room temperature. Then, the sample is incubated in 50 ml deionized water at 80° C. for 24 hours. Afterwards, the amount of alkali metal ions in the water is determined via inductively coupled plasma optical emission spectrometry (ICP-OES). The alkali leaching factor is defined as the ratio of the amount of alkali metal ions in the water (in pmol) per surface area of the material sample (in dm²).

### Acid Leaching Factor

It is also advantageous if the inorganic material has a high acid resistance. Therefore, before, after and/or without chemical toughening the acid leaching factor of the material may be at most 20 μmol/dm², at most 10 μmol/dm², at most 5 μmol/dm², or even at most 3 μmol/dm².

For determining the acid leaching factor, a material sample is first washed in deionized water for 8 minutes at 80° C. and subsequently rinsed with deionized water at room temperature. Then, the sample is incubated in 100 ml of nitric acid with a concentration of 0.01 mol/l at 100° C. for 1 hour. Afterwards, the amount of alkali metal ions in the acid solution is determined via inductively coupled plasma optical emission spectrometry (ICP-OES). The acid leaching factor is defined as the ratio of the amount of alkali metal ions in the acid solution (in pmol) per surface area of the material sample (in dm²).

The inorganic material layer can be a chemically toughened glass layer having a thickness (t) of less than 0.4 mm, a first surface and a second surface and a compressive stress region extending from the first surface to a first depth in the glass layer (DoL), the region is defined by a compressive stress (CS) wherein a surface CS at the first surface is at least 100 MPa. The first surface and the second surface are located on opposite sides of the glass layer.

### Breakage Height

The inorganic material layer can have a breakage height (given in mm) of at least the figure of the thickness (t in mm) of the layer multiplied by 50, or 60, or 70, or 80. The breakage height is determined in a sandpaper ball drop test. In this test, the layer is placed with a second surface on a steel plate and a first surface of the layer is loaded until breakage by a 4.5 g acrylic ball dropped from above wherein a sandpaper of type P180 is placed on the first surface of the layer wherein the abrasive side of the sandpaper is in contact with the first surface. The dropping height is increased until the layer breaks. The last height at which the layer did not break is considered the breakage height.

The layer can have a breakage height (given in N) of ≥50*t in the above mentioned sandpaper ball drop test (t being the figure of the respective thickness of the layer in the unit “mm”).

Surprisingly it was found by the inventors that the breakage height criterion for a layer can be described by the mentioned factor 50 and the thickness of the layer. The factor will be valid if the breakage height of the layer is determined in the sandpaper ball drop test. In this dynamic test, the layer is placed with a second surface on a steel plate and a first surface of the layer (which in the case of a glass layer may or may not be chemically toughened) is orientated upwards. An acrylic ball having a weight of 4.5 g is dropped from above onto the layer. Step by step the drop height of the ball is increased until the layer breaks wherein there is one drop per each step and the distance between each step is chosen reasonably, such as 2 mm or 5 mm. The test is performed on small samples (11 mm×11 mm) at room temperature of about 20° C. and relative humidity of about 50% using sandpaper P180 according to ISO 6344 (e.g. #180 Buehler sandpaper manufactured by the company “Buehler”). If a layer of larger size is to be tested, small samples will be cut out using a diamond cutting wheel. No further edge treatment is performed on the small samples. The breakage height (also called “sandpaper ball drop height”) is the maximum height that can be applied before the layer breaks. Breaking means that the layer gets a visible surface crack (crack is generated) or breaks into two or several pieces. The breakage is determined with the naked eye.

This test is adjusted to and is especially suitable for layers and reproduces in a quite simple manner the above mentioned problem, that is the impact contact between the layer and a sharp hard object when the layer falls down or is hit.

### Breakage Bending Radius

Further the inorganic material layer and/or the protective cover can have a breakage bending radius (given in mm) of less than the thickness (t in mm) of the layer multiplied by 100,000, wherein the result is divided by the figure of the surface compressive stress (in MPa) measured at the surface of the inorganic material layer.

Inorganic material layers of this disclosure can have an optimized stress profile. It has the balance between small bending radius and high sharp contact resistance such as impact resistance. Surprisingly it was found that the layer will be reasonable strong enough to accommodate the applications of protective covers especially in daily use, particularly if the following conditions are fulfilled:

In the case of an inorganic material layer made of glass its breakage bending radius (given in mm) may be <100,000*t/CS, wherein t is the thickness of the glass layer (given in the unit “mm”) and CS is the figure of the measured surface compressive stress (given in the unit “MPa”). That means in the latter calculation, the product is divided by a figure which corresponds to the respective measured surface compressive strength (given in MPa) at the first surface of the glass layer.

By means of these criteria it can be decided whether a layer is suitably strong and flexible enough to be used for the respective application before it becomes part of a protective cover. It was surprisingly found that the breakage height is strongly related to layer thickness. Therefore, thinner layers are especially sensitive to breakage caused by impacts with hard and sharp objects.

In advantageous embodiments of the disclosure, the breakage bending radius (in mm) of a chemically toughened glass layer (i.e. inorganic material layer) is less than the thickness (t in mm) of the glass layer multiplied by 100,000 or 80,000 wherein the result is divided by the figure of the surface compressive stress (in MPa) measured at the first surface (<t*80,000/CS). Preferably, the breakage bending radius (in mm) can be less than the thickness (t in mm) of the inorganic material layer multiplied by 70,000 wherein the result is divided by the figure of the surface compressive stress (in MPa) measured at the surface (<t*70,000/CS). In some variants the breakage bending radius (in mm) can be less than the thickness (t in mm) of the inorganic material layer multiplied by 60,000 wherein the result is divided by the figure of the surface compressive stress (in MPa) measured at the first surface (<t*60,000/CS). Surprisingly it was found by the inventors that the breakage bending radius criterion for a glass layer as the inorganic material layer can be described by the inventive factor 100,000, the thickness and measured surface CS of the glass layer. The inventive factor will be valid if the breakage bending radius of the inorganic material layer is determined in a 2 point bending test as described now. The breakage bending radius is determined by using a UTM (universal testing machine) on small samples (20 mm×70 mm) at room temperature of about 20° C. and relative humidity of about 50%. If a glass layer of larger size is to be tested, small samples will be cut out using a diamond cutting wheel. No further edge treatment is performed on the small samples. The inorganic material layer is brought into a bent position and its opposite ends are positioned between two parallel plates (steel plates). Then the distance between the plates is lowered continuously so that the bending radius of the inorganic material layer decreases until breakage wherein the loading speed is 60 mm/min. The distance between the plates is recorded when the inorganic material layer is kinking or damaging or breaking into two or several piece which is determined by the signal of the UTM software. From that distance the corresponding bending radius of the inorganic material layer at the time of breakage is calculated.—If glass layers with treated edges are tested (wherein the glass layers may be for example edge treated by CNC grinding, etched by acid (e.g. HCl, HNO₃, H₂SO₄, NH₄HF₂, or mixtures thereof) and then optionally toughened), the bending radius will even be smaller compared to corresponding inorganic material layer without treated edges because edge treatment increases the strength and thus decreases the bending radius.

This 2 point bending test is adjusted to and is especially suitable for inorganic material layers such as glass layers and reproduces in a quite simple manner the above mentioned problem, that is the bending of a glass layer upon loading it. In this context of the invention it was found out that the 2 point bending method is more meaningful than other known bending strength tests such as 3 and 4 point bending tests.

As mentioned above an inorganic material layer can have quite different sizes. Therefore, in the course of determining the breakage height and breakage bending radius the following has to be taken into account:

In the case of larger layers (e.g. a glass roll or a large glass sheet), a plurality of samples are measured regarding breakage height using the sandpaper ball drop test. For this a random sample N values is taken. N should be high enough to obtain a statistically ensured average value. Preferably at least 20, more preferably at least 30 samples are tested. The number of samples depends on the respective size of the layer to be tested. The measured values are statistically evaluated using Weibull method. B10 value of Weibull distribution (that is the calculated height (in mm) wherein 10% of the samples are broken) is determined and taken to represent the claimed breakage height.

However, in the case of small layers, such as layers having less than 25 cm², (e.g. an individual small cover glass) a single measured value of breakage height is sufficient and is taken to represent claimed breakage height.

In the case of a number of measured values between 2 and 19, the average of measured breaking height is taken to represent the claimed breakage height.

For the breakage bending radius an average value can be calculated. For this a random sample of N values is taken. The number of samples depends on the respective size of the layer to be evaluated. Preferably N should be high enough to obtain a statistically ensured average value. Preferably at least 20, more preferably at least 30 samples are tested. Thus, a random sample of N values is taken for the breakage bending radii R₁ . . . R_{N}, and, for the values of these random samples, the average value

$$〈 R 〉 = \frac{1}{N} {\sum }_{i = 1}^{N} {R}_{i}$$

and the variance

$$s = \sqrt{\frac{1}{N - 1} {\sum }_{i = 1}^{N} {( {R}_{i} - 〈 R 〉 )}^{2}}$$

are calculated.

The average breakage bending radius is taken to represent claimed breakage bending radius. However, in the case of small layers, such as layers having less than 25 cm², (e.g. an individual small cover glass) a single measured value of breakage bending radius is sufficient and is taken to represent claimed breakage bending radius. Average value and variance of the breakage height are calculated accordingly.

### Survival Parameter

It is one object of this disclosure to provide a protective cover that has improved resistance to bending and folding. In other words, the inorganic material layer and the whole protective cover should have a high likelihood of withstanding bending and folding. High likelihood of withstanding bending and folding should be maintained even in the case of scratches or impact forces imparted on the cover and especially on the inorganic material layer.

In an embodiment, the present disclosure comprises a protective cover that has an inorganic material layer comprising or consisting of a transparent material that may have a certain brittleness. The inorganic material layer has a fracture toughness K_{IC}, a compressive stress CS, a characteristic depth of penetration x_{c} and a thickness d, wherein the layer complies with the following equation:

$$\frac{395 \cdot {K}_{Ic}}{\sqrt{m}} = \ddot{U} P \cdot ( \frac{π}{2} - arcsin ( \frac{B}{4 \cdot {10}^{- 6} \cdot m} ) - \frac{2}{d} \cdot \sqrt{( 1 , 6 \cdot {10}^{- 11} \cdot {m}^{2} - {B}^{2} )} ) + CS \cdot ( ( 1 - \frac{{x}_{c}}{0 \text{,} 843 \cdot d} ) \cdot ( \frac{π}{2} - arcsin ( \frac{B}{4 \cdot {10}^{- 6} \cdot m} ) ) - \frac{0 \text{,} 843 \cdot \sqrt{( 1 , 6 \cdot {10}^{- 11} \cdot {m}^{2} - {B}^{2} )}}{{x}_{c}} ) , \\ wherein B = \frac{{x}_{c}}{0 \text{,} 843} \cdot ( \frac{d}{CS \cdot d + 2 \text{,} 37 \cdot \ddot{U} P \cdot {x}_{c}} ) \cdot ( \ddot{U} P + CS - \frac{CS \cdot {x}_{c}}{0 \text{,} 843 \cdot d} ) for 0 \leq \frac{{x}_{c}}{0 \text{,} 843} \cdot ( \frac{d}{CS \cdot d + 2 \text{,} 37 \cdot \ddot{U} P \cdot {x}_{c}} ) \cdot ( \ddot{U} P + CS - \frac{CS \cdot {x}_{c}}{0 \text{,} 843 \cdot d} ) \leq 4 \cdot {10}^{- 6} , \\ wherein B = 0 for 0 > \frac{{x}_{c}}{0 \text{,} 843} \cdot ( \frac{d}{CS \cdot d + 2 \text{,} 37 \cdot \ddot{U} P \cdot {x}_{c}} ) \cdot ( \ddot{U} P + CS - \frac{CS \cdot {x}_{c}}{0 \text{,} 843 \cdot d} ) , \\ wherein B = 0 for \frac{{x}_{c}}{0 \text{,} 843} \cdot ( \frac{d}{CS \cdot d + 2 \text{,} 37 \cdot \ddot{U} P \cdot {x}_{c}} ) \cdot ( \ddot{U} P + CS - \frac{Cs \cdot {x}_{c}}{0 \text{,} 843 \cdot d} ) > 4 \cdot {10}^{- 6} ,$$

wherein m=1 meter,

wherein x_{c}>0 μm, and

wherein ÜP (survival parameter) is more than 250 MPa.

In a preferred embodiment, the present disclosure provides a set of protective covers, or at least one protective cover comprising a set of inorganic material layers, wherein the number n of layers in the cover or covers is at least 2, 3, 4, 5, 10, 20, 50 or even at least 100.

In accordance with this description a material is considered brittle, if it has a brittleness S of more than 0.1 μm^{-1/2}, preferably more than 0.2 μm^{-1/2}, more than 0.5 μm^{-1/2}, more than 0.8 μm^{-1/2}, more than 1 μm^{-1/2}, more than 1.5 μm^{-1/2} more than 2 μm^{-1/2}. Preferably, the brittleness S is up to 20 μm^{-1/2}, up to 18 μm^{-1/2}, up to 15 μm^{-1/2}, up to 12 μm^{-1/2}, up to 10 μm^{-1/2} up to 9 μm^{-1/2}, or up to 8 μm^{-1/2}. Preferably, the brittleness S is in a range of from 0.1 μm^{-1/2} to 20 μm^{-1/2}, preferably from 0.2 μm^{-1/2} to 18 μm^{-1/2}, preferably from 0.5 μm^{-1/2} to 15 μm^{-1/2}, in particular from 0.8 μm^{-1/2} to 12 μm^{-1/2}, or from 1 μm^{-1/2} to 10 μm^{-1/2}, preferably from 1.5 μm^{-1/2} to 9 μm^{-1/2}, more preferred from 2 μm^{-1/2} to 8 μm^{-1/2}. The brittleness S is calculated as the ratio of Vickers hardness H and fracture toughness K_{IC} according to the following equation.

S=H/K_{IC}

This ratio is used as a measure for the brittleness in “Lawn, B. R.; Marshall D. B.; «Hardness, Toughness, and Brittleness: An Indentation Analysis»; Journal of the American Ceramic Society (1979)“. The skilled person knows how this brittleness is determined experimentally. Preferably, the brittleness is determined according to the explanations given in” Sehgal, J.; Ito, S.; «Brittleness of glass»; Journal of Non-Crystalline Solids (1999)”.

The transparent and optionally also brittle inorganic material is preferably selected from the group consisting of glass, glass-ceramic, ceramic and crystals. Preferred crystals are selected from the group consisting of sapphire, diamond, chromium, ruby, topaz, quartz and orthoclase. Sapphire is the preferred crystal. Preferably, the transparent and optionally also brittle material is glass or glass ceramic, in particular glass. Particularly, the material may be borosilicate glass, or aluminosilicate glass. Preferably, the proportion of Li₂O+Na₂O in the material is more than 1% by weight, more preferably more than 3% by weight, more preferably more than 5% by weight. In particularly preferred embodiments, the material contains Na₂O but is free of Li₂O, Rb₂O and Cs₂O.

When bending a brittle material without further measures, tensile stress is observed on the convex surface of the material, which leads to breakage when exceeding a threshold. It was found that bendable or even foldable articles, such as inorganic material layers of the protective cover of this invention, can be made when choosing the parameters fracture toughness K_{IC}, compressive stress CS, characteristic depth of penetration x_{c} and thickness d such that according to the equation given above, the survival parameter ÜP is more than 250 MPa. The survival parameter has the dimension of a tensile stress and is given in MPa. It was surprisingly found that an article such as an inorganic material layer of transparent or even brittle material is particularly bendable, if the mentioned parameters are chosen such that the survival parameter is more than 250 MPa, preferably at least 300 MPa, at least 350 MPa, at least 400 MPa, at least 450 MPa, at least 500 MPa, at least 600 MPa, at least 700 MPa or even at least 800 MPa. Preferably, the survival parameter is up to 1,000,000 MPa, up to 100,000 MPa, up to 20,000 MPa, up to 10,000 MPa, up to 7500 MPa, up to 5000 MPa, up to 4000 MPa, up to 3000 MPa, or even up to 2000 MPa. Preferably, the survival parameter is within a range of from 250 MPa to 1,000,000 MPa, 300 MPa to 100,000 MPa, 350 MPa to 20,000 MPa, 400 MPa to 10,000 MPa, 450 MPa to 7500 MPa, 500 MPa to 5000 MPa, 600 MPa to 4000 MPa, 700 MPa to 3000 MPa, 800 MPa to 2000 MPa.

The fracture toughness K_{IC} is preferably the fracture toughness under tensile stress (mode I). The fracture toughness is given in MPa*√m and is preferably measured according to the Precracked Beam Method given in ASTM C1421-15 (p. 9 et seqq.). The fracture toughness K_{IC} is preferably determined with one or more reference articles. The reference articles used for determining the fracture toughness K_{IC} are preferably not toughened, in particular not chemically toughened. Preferably, the fracture toughness is more than 0.4 MPa*√m. Preferably, the fracture toughness is at least 0.45 MPa*√m, more preferred at least 0.5 MPa*√m, preferably at least 0.6 MPa*√m, at least 0.7 MPa*√m, at least 0.8 MPa*√m, at least 0.9 MPa*√m, or at least 1 MPa*√m, or at least 1.1 MPa*√m, or at least 2 MPa*√m. Preferably, the fracture toughness is up to 100 MPa*√m, up to 75 MPa*√m, up to 50 MPa*√m, up to 10 MPa*√m, in particular, up to 8 MPa*√m, or up to 5 MPa*√m.

The shape of a chemical toughening profile corresponds to an inverse error function. The diffusion coefficient D is different for different ion species, different temperatures and different materials. The diffusion coefficient D is measured in units of m²/s. From the diffusion coefficient D and the toughening time t the characteristic depth of penetration x_{c} can be calculated using the equation: x_{c}=2√\sqrt{D·t}. The toughening time t is the time that the article, e.g. the inorganic material layer, is kept in the salt bath. Diffusion coefficient D can be measured with different methods. Preferably, diffusion coefficient D is calculated from the depth profile of the exchanged ions after defined toughening temperature and time. This depth profile can for example be measured using EDX (energy dispersive x-ray spectroscopy). Alternatively, the ToF-SIMS (Time-of-Flight Secondary Ion Mass Spectrometry) method can be used. In the ToF-SIMS method material is released from the surface of the article, e.g. the inorganic material layer, by an ion beam and the proportions of the thus released ions are measured. By releasing material from the surface the ion beam basically “bores” into the depth of the article, e.g. the inorganic material layer, so that changes in the ion profile can be determined. Further suitable methods are known to the skilled person.

The characteristic depth of penetration has the unit of a length. Preferably, it is at least 2 μm, at least 3 μm, at least 0.843*4 μm, preferably at least 4 μm, at least 6 μm, at least 8 μm, or at least 10 μm. Preferably, the characteristic depth of penetration is up to 50 μm, up to 30 μm, up to 27 μm, to 25 μm, up to 24 μm, up to 22 μm, or up to 20 μm.

In preferred embodiments, the characteristic depth of penetration should not exceed certain values in relation to the thickness d of the inorganic material layer. Preferably, the characteristic depth of penetration is up to d/2, up to d/3, up to d/3.5, up to d/4, up to d/5, up to d/6, or up to d/7. However, the characteristic depth of penetration should be at least d/40, at least d/30, at least d/27, at least d/25, at least d/20, at least d/15, or at least d/10.

The tensile stress on the convex side of the inorganic material layer is roughly proportional to the Young's modulus of the material. Thus, it is preferred for the survival of the bendable and preferably foldable protective cover and inorganic material layer that the Young's modulus should not be too high. Preferably, the Young's modulus of the inorganic material is up to 200 GPa, preferably up to 150 GPa, up to 120 GPa, or up to 100 GPa, or up to 90 GPa. Preferably, the Young's modulus of the inorganic material is at least 40 GPa, at least 50 GPa, at least 60 GPa or at least 70 GPa, or at least 80 GPa, or at least 90 GPa, or at least 100 GPa.

The survival of a bendable and optionally foldable protective cover and/or inorganic material layer can be improved, if tensile stress is relocated outside of the article. In accordance with this invention this can be achieved by disposing a further material on the side of the article that is subjected to the tensile stress. The further material may cover the whole area of the respective side of the article, or it may cover parts of the respective side of the article. In preferred embodiments, strips of metal or polymeric material are arranged on at least one side of the article, such as on the inorganic material layer and/or on the protective cover, in particular on the side that is subject to tensile stress. Metal has the advantage of a higher Young's modulus, a polymeric material may have the benefit of being transparent. The one or more strips of metal or polymeric material may be arranged close to the edges of the inorganic material layer and/or on the protective cover, such as within a distance equivalent of not more than 30%, 20%, or 10% of the width of the layer from the respective edge or within a distance of at least 10*d but not more than 50*d, preferably not more than 20*d from the respective edge, wherein “d” is the thickness of the inorganic material layer. Preferably, this applies to the edges extending perpendicularly to the bending or folding axis, in particular along the length direction of the inorganic material layer, i.e. in the direction of the longitudinal axis. A strip of further material may be used, which has a width which is less than 30%, 20%, 10%, 5%, 3%, or 1% of the width of the inorganic material layer. The width may be at least 0.1%, at least 0.3%, or at least 0.9% of the width of the inorganic material layer and/or the protective cover.

The further material may have a Young's modulus of more than 10 GPa, preferably at least 20 GPa, at least 50 GPa, at least 75 GPa or at least 100 GPa. In preferred embodiments, the further material has a Young's modulus of up to 1000 GPa, preferably up to 800 GPa, up to 700 GPa, or up to 650 GPa. In particular, compared to the Young's modulus of the inorganic material of the inorganic material layer, the further material has a value of the Young's modulus that is within the range of from 1/10 to 10 times the value of the Young's modulus of the inorganic material, preferably within a range of ⅕ up to 5 times, or within a range of from ½ to 2 times.

The brittleness S of the further material is preferably less than 20 μm^{-1/2}, less than 10 μm^{-1/2}, less than 5 μm^{-1/2}, less than 2 μm^{-1/2}, less than 1 μm^{-1/2}, or less than 0.5 μm^{-1/2} less than 0.25 μm^{-1/2}, less than 0.1 μm^{-1/2}, less than 0.05 μm^{-1/2} or less than 0.005 μm^{-1/2}. Preferably, the thickness of the further material is within a range of from 0.2*d to 5*d, preferably within a range of from 0.5*d to 2*d, wherein d is the thickness of the inorganic material layer. Preferably, the thickness of the further material is at least 10 μm, preferably at least 50 μm, at least 100 μm, at least 200 μm, or at least 500 μm. Particularly, the thickness of the further material should not exceed 5 mm, 4 mm, 3 mm, 2 mm or 1 mm. Preferably, the further material is selected from the group of polymers, such as plastics, and metallic materials, such as metals or metal alloys. A preferred plastic material is polyethylene.

As described above, the tensile stress is preferably relocated out of the article and into the further material. Therefore, it is advantageous if the further material has a comparably high offset yield point (or proof stress). Preferably, the 0.2% offset yield point of the further material, in particular of a metallic material, is at least 50 N/mm², more preferably at least 75 N/mm², more preferably at least 100 N/mm², more preferably at least 150 N/mm². The 0.2% offset yield point is the (uniaxial) mechanical tension at which the persistent elongation after load relief is 0.2% based on the initial length of the sample. The 0.2% offset yield point can be unambiguously determined from the stress-strain curve.

It is also advantageous if the further material has a comparably high tensile strength. Preferably, the tensile strength of the further material, in particular of polymeric plastics, is at least 50 N/mm², more preferably at least 60 N/mm², more preferably at least 70 N/mm², more preferably at least 80 N/mm². The tensile strength is preferably determined according to one of the following standards: EN ISO 6892-1, ISO 6892, ASTM E 8, ASTM E 21, DIN 50154, ISO 527, ASTM D 638.

It has been found that geometrical effects in the inorganic material layer lead to a reduction of compressive stress at the edges of the layer. This effect can be produced by rounding the edges. It has turned out that it is advantageous that thickness of the inorganic material layer d, characteristic depth of penetration x_{c} and rounding radius OVR are within the following relationship.

d/3>OVR>x_{c}/5

Preferably, the rounding radius OVR is less than d/3 and higher than x_{c}/5. The rounding radius is measured at lateral fractures of respective inorganic material sheets. The rounding radius is the radius of the largest possible circle that can be fitted to the edge of the lateral fracture. The edge is the cross-section at the edge of the original sheet. Preferably, the OVR of individual articles is measured indirectly by using one or more reference articles that allow conclusions regarding the OVR of the individual articles. For example, it is possible to determine the OVR of articles of a particular lot or batch by determining the OVR of one or more reference articles of the respective lot or batch provided that there are no or only insignificant differences between the individual articles of a lot or batch. Insignificant differences are preferably differences of at most 20%, more preferably at most 15%, more preferably at most 10%, more preferably at most 5%, more preferably at most 2%, more preferably at most 1% between the maximum and minimum values within a respective lot or batch.

### Strength Parameter OFP

The effectiveness of the compressive stress profile on the survival of a bent article can be shown by strength measurement of the respective inorganic material layer. Two point bending measurements were conducted, wherein the strengths were measured according to Matthewson and Kurkjian (J. Am. Ceram. Soc., 69 [11], Seiten 815-821 (1986)). Preferably, the strength of individual articles is measured indirectly by using one or more reference articles that allow conclusions regarding the strength of the individual articles. For example, it is possible to determine the strength of articles of a particular lot or batch by determining the strength of one or more reference articles of the respective lot or batch provided that there are no or only insignificant differences between the individual articles of a lot or batch. Insignificant differences are preferably differences of at most 20%, more preferably at most 15%, more preferably at most 10%, more preferably at most 5%, more preferably at most 2%, more preferably at most 1% between the maximum and minimum values within a respective lot or batch.

It was found that the inorganic material layer is particularly resistant against breakage, if a specific relationship between the mean values, MW, of the strength measurements, the standard deviation STABW, the number N of specimens within a measurement and the strength parameter OFP, which is calculated according to the following formula.

$$OFP = 0 \text{,} 4 \cdot exp ( - \frac{N}{9} ) + \frac{MW ( 1 \text{,} 3 - 0 \text{,} 25 \cdot exp ( - \frac{N}{8} ) )}{STABW} - 0 \text{,} 5$$

Preferably, OFP is at least 2, more than 4, at least 5, at least 10, or at least 20. In particular, OFP is up to 100, up to 80, up to 70, or up to 60.

### Crack Initiation Load

The crack initiation load is the resistance against the formation of cracks upon intrusion of a body. The crack initiation load is essentially applicable to events of impact onto the article, such as onto the inorganic material layer. A comparably high crack initiation load is preferred. At 50% relative humidity of the air, the crack initiation load of the inorganic material layer is preferred to be at least 1.5 N, at least 3 N, at least 5 N, or at least 10 N. In particular, the crack initiation load may be up to 200 N, up to 150 N, up to 75 N, up to 65 N, up to 55 N, up to 45 N, or up to 30 N. The crack initiation load is measured with a Vickers indenter as described by Sehgal and Ito (J. Am. Ceram. Soc., 81 [9], pages 2485-2488 (1998)).

A further aspect that is of relevance concerning the impact resistance of the inorganic material layer is the critical compression. The critical compression is the compressive stress limit that a material can endure before it forms cracks. This value relates to a strain and does not have a unit. Preferably, the critical compression of the inorganic material layer is at least 8%, or at least 10%. The critical compression can be determined using cylinder compression. A specimen of the article to be investigated may be put between the end faces of 2 cylinders so that pressure can be exerted on the specimen by the cylinders. A universal measuring apparatus, e.g. INSTRON 6025, can be used to perform this method.

In an embodiment, the inorganic material layer comprises a glass or glass ceramic as described below. Preferably, the inorganic material layer consists of the below described material.

In an embodiment, the inorganic material layer is a chemically toughened glass layer. In other embodiments, the inorganic material layer may be a glass layer, which has not undergone chemical toughening. Or the inorganic material may be a material that has been chemically toughened partially.

The inorganic material layer may be a chemically toughened glass layer having a thickness (t) of less than 0.4 mm, a first surface and a second surface and a compressive stress region extending from the first surface to a first depth in the glass layer (DoL), the region is defined by a compressive stress (CS) wherein a surface CS at the first surface is at least 100 MPa. The first surface and the second surface are located on opposite sides of the glass layer.

### Breakage Force

The inorganic material layer and/or the protective cover may have a breakage force (given in N) of at least the figure of the thickness (t in mm) of the layer multiplied by 30. The breakage force is determined in a sandpaper press test. In this test, the layer is placed with its second surface on a steel plate and the first surface of the layer is loaded and pressed until breakage by a steel rod having a diameter of 3 mm at its flat front face wherein a sandpaper of type P180 is placed between the front face of the steel rod and the first surface of the layer wherein the abrasive side of the sandpaper is in contact with the first surface. Further the layer according to the present disclosure can have a breakage bending radius (given in mm) of less than the thickness (t in mm) of the layer multiplied by 100,000, wherein the result is divided by the figure of the surface compressive stress (in MPa) measured at the first surface.

An inorganic material layer may have an optimized stress profile. It has the balance between small bending radius and high sharp contact resistance especially press resistance. Surprisingly it was found that the layer will be strong enough to accommodate the applications in daily use of an electronic device, particularly if the following conditions are fulfilled:

The inorganic material layer and/or the protective cover may have a breakage force (given in N) of ≥30*t, 40*t, 50*t, or 60*t in the above mentioned sandpaper test (t being the figure of the respective thickness of the layer in the unit “mm”) and/or its breakage bending radius (given in mm) may be <100,000*t/CS, wherein t is the thickness of the layer (given in the unit “mm”) and CS is the figure of the measured surface compressive stress (given in the unit “MPa”). That means in the latter calculation, the product is divided by a figure which corresponds to the respective measured surface compressive strength (given in MPa) at the first surface of the layer.

By means of these criteria it can be decided whether an inorganic material layer is suitably strong and flexible enough to be used for the respective application before it becomes part of a protective cover. It was surprisingly found that the breakage force is strongly related to layer thickness. Therefore, thinner layers are especially sensitive to breakage caused by contacts with hard and sharp objects.

Surprisingly it was found by the inventors that the breakage force criterion for an inorganic material layer can be described by the mentioned factor 30 and the thickness of the layer. The factor will be valid if the breakage force of the layer is determined in the sandpaper press test recorded by using universal testing machine (UTM). In this test, the layer is placed with its second surface on a steel plate and the first surface of the layer (which may be chemically toughened) is loaded and pressed until breakage by a steel rod having a diameter of 3 mm at its flat front face wherein a sandpaper of type P180 is placed between the front face of the steel rod and the first surface of the layer wherein the abrasive side of the sandpaper is in contact with the first surface. The longitudinal axis of the steel rod is oriented vertically to the first surface of the layer. The steel rod is moved in a direction corresponding to its longitudinal axis with a continuously applied loading speed of 1 mm/min until breakage. The test is performed on small samples (11 mm×11 mm) at room temperature of about 20° C. and relative humidity of about 50% using sandpaper P180 according to ISO 6344 (e.g. #180 sandpaper manufactured by the company “Buehler”). If an inorganic material layer of larger size is to be tested, small samples will be cut out using a diamond cutting wheel. No further edge treatment is performed on the samples. The sample is pressed by the rod until it breaks (crack is generated). The breakage force (also called “sandpaper press force”) is the maximum force that can be applied until the layer breaks. Breaking means that the layer exhibits a surface crack or breaks into two or more pieces. The breakage is determined with the signal of the UTM software.

This test is adjusted to and is especially suitable for inorganic material layers and reproduces in a quite simple manner the above mentioned problem, that is the press contact between the layer (e.g. a FPS or a touch display) and a sharp hard object. Preferably, the herein described tests applied to the inorganic material layer are conducted before the layer is processed into a protective cover of this disclosure.

As described above inorganic material layers are used in many fields of daily applications, e.g. as cover for finger print sensors especially in smartphones and tablets. To increase the strength of the cover toughening, such as chemically toughening, may be performed. In this context, in the prior art it was generally assumed that a high compressive stress and a high DoL is necessary to ensure the flexibility and strength of the inorganic material, e.g. glass. Thus, such a known toughened glass layer usually has a high compressive stress (CS) and a DoL of >20 μm, which leads to a high central tension (CT) in the inner part of the glass. However, it was surprisingly found by the inventors that the sharp contact resistance of such known toughened glasses decreases quickly with increasing DoL and reaches a minimum value when the ratio between DoL (given in μm) and thickness (given in μm) is roughly between 0.1 to 0.2, if there is no additional surface protection against sharp contact. In certain embodiments, the ratio DoL/d is less than 0.2. Thus, if a conventional toughened glass layer is pressed or impacted by objects with high hardness (e.g. sand grains sticking to the finger while pressing the cover glass of a FPS) a crack will result that extends through the strengthened layer of the cover glass (that is defined by a compressive stress (CS)) and reaches the tensile part of the glass even if the contact force has been quite low. Due to the high central tensile stress existing in that glass region the known glass article cracks spontaneously and the cover glass is damaged.

Surprisingly it was found by the inventors that the inorganic material layers used according to the invention are more reliable concerning flexibility and contact resistance in the further processing and daily use. In certain embodiments, the reason for that may be the improved and optimized stress profile of the layers according to the present disclosure. The other way round, if an inorganic material layer meets the claimed breakage force and the claimed breakage bending radius (referred to its respective thickness and measured surface CS), the breakage risk of the layer when being used (e.g. in a protective cover) is low.

As mentioned above an inorganic material layer can have quite different sizes. Therefore, in the course of determining the breakage force and breakage bending radius the following has to be taken into account:

In the case of larger layers (e.g. a large glass sheet), a plurality of samples are measured regarding breakage force using the sandpaper press test. For this a random sample N values is taken. N should be high enough to obtain a statistically ensured average value. Preferably at least 20, more preferably at least 30 samples are tested. The number of samples depends on the respective size of the layer to be tested. The measured values are statistically evaluated using Weibull method. B10 value of Weibull distribution (that is the calculated force (in N) wherein 10% of the samples are broken) is determined and taken to represent the claimed breakage force.

However, in the case of small layers (e.g. an individual small protective cover glass) a single measured value of breakage force is sufficient and is taken to represent the breakage force.

In the case of a number of measured values between 2 and 19, the average measured breaking force is taken to represent the breakage force.

### Inorganic Material

In one embodiment, the inorganic material of the at least one inorganic material layer and/or of any additional inorganic material layer is an alkali-containing glass, such as alkali aluminosilicate glass, alkali silicate glass, alkali borosilicate glass, alkali aluminoborosilicate glass, alkali boron glass, alkali germanate glass, alkali borogermanate glass, alkali soda lime glass, and combinations thereof. The inorganic material layer is bendable or even foldable. Generally, the outer layers of a protective cover are subject to tensile stresses due to bending or folding, impact stresses, for example, due to articles falling onto the protective cover, and stresses due to scratching with hard articles.

The inorganic material may be borosilicate glass, soda lime glass, lithium aluminum silicate glass, or a glass ceramic.

In preferred embodiments, the inorganic material of the inorganic material layer comprises a glass, or consists of a glass, which may be characterized by one or more of the following compositional features as set out below as glass composition I or II.

### Glass Composition I

In this description we refer to the cationic compositions of the glasses. In these compositions—if nothing else is indicated—“silicon” refers to Si⁴⁺, “boron” refers to B³⁺, “aluminum” refers to Al³⁺, “lithium” refers to Li⁺, “sodium” refers to Na⁺, “potassium” refers to K⁺, “magnesium” refers to Mg²⁺, “calcium” refers to Ca²⁺, “barium” refers to Ba²⁺, “zinc” refers to Zn²⁺, “titanium” refers to Ti⁴⁺, “zirconium” refers to Zr⁴⁺, “arsenic” refers to the sum of As³⁺ and As⁵⁺, “antimony” refers to the sum of Sb³⁺ and Sb⁵⁺, “iron” refers to the sum of Fe³⁺ and Fe⁺, “cerium” refers to the sum of Ce³⁺ and Ce⁴⁺, “tin” refers to the sum of Sn²⁺ and Sn⁴⁺, and “sulfur” relates to the total amount of sulfur in all its valence states and oxidation levels.

The glasses have certain preferred compositions that will be outlined below. The glasses generally comprise cationic and anionic components. The composition of cations in the glass will be given in cationic percentages (cat.-%), i.e. indicating the molar proportion of the respective cation relative to the total molar amount of cations in the composition. Preferably, the glasses comprise the following components, in cat.-%, based on the total molar amount of cations in the glass: silicon 40 to 75 cat.-%, boron 0 to 23 cat.-%, aluminum 0 to 20 cat.-%, lithium 0 to 18 cat.-%, sodium 0 to 25 cat.-%, potassium 0 to 15 cat.-%, magnesium 0 to 10 cat.-%, calcium 0 to 9 cat.-%, barium 0 to 4 cat.-%, zinc 0 to 7 cat.-%, titanium 0 to 5 cat.-%, zirconium 0 to 3 cat.-%. In preferred embodiments, the cations in the glasses consist of the cations mentioned in the before-mentioned list to an extent of at least 95%, more preferably at least 97%, most preferably at least 99%. In most preferred embodiments, the cationic component of the glass essentially consists of the mentioned cations.

As anionic components the glass preferably comprises at least one anion selected from fluorine (F⁻), oxygen (O²⁻), chloride (Cl⁻). Most preferably, the anions present in the glass consist of oxygen to an extent of at least 95%, more preferably at least 97%, most preferably at least 99%. In most preferred embodiments, the anionic component of the glass essentially consists of oxygen.

The terms “X-free” and “free of component X”, respectively, as used herein, preferably refer to a glass, which essentially does not comprise said component X, i.e. such component may be present in the glass at most as an impurity or contamination, however, is not added to the glass composition as an individual component. This means that the component X is not added in essential amounts. Non-essential amounts according to the present invention are amounts of less than 100 ppm (n/n), preferably less than 50 ppm and more preferably less than 10 ppm. Thereby “X” may refer to any component, such as lead cations or arsenic cations. Preferably, the glasses described herein do essentially not contain any components that are not mentioned in this description.

A particularly preferred glass composition comprises the following components, in cat.-%, based on the total molar amount of cations in the glass: silicon 45 to 60 cat.-%, aluminum 14 to 20 cat.-%, sodium 15 to 25 cat.-%, potassium 1.5 to 8.5 cat.-%, magnesium 2 to 9, zirconium 0.1 to 1.3 cat.-%, cerium 0.01 to 0.3 cat.-%. In preferred embodiments, the cations in the glass consist of the cations mentioned in the before-mentioned list to an extent of at least 95%, more preferably at least 97%, most preferably at least 99%. In most preferred embodiments, the cationic components of the glass essentially consist of the mentioned cations.

Preferably, the glass comprises silicon in proportions of 40 to 75 cat.-%, more preferably in proportions of 45 to 60 cat.-%. Silicon is an important network former in the glass matrix which is very important for the glass properties. In particular, silicon cations are important for the chemical resistance, hardness and scratch resistance of the glass. In preferable embodiments the glasses comprise at least 41 cat.-% of silicon, more preferably at least 42 cat.-% of silicon, still more preferably at least 43.5 cat.-% of silicon, and most preferably at least 45 cat.-% of silicon. However, contents of silicon cations which are too high may result in an increase of the glass transition temperature, making glass production uneconomical. Therefore, it is particularly preferable that the content of silicon cations is at most 75 cat.-%, further preferable at most 70 cat.-%, still more preferable at most 65 cat.-%, and most preferable at most 60 cat.-%.

Besides silicon cations the glass can also comprise at least one second network former. The glasses may contain boron cations as an additional network former in proportions of 0 to 23 cat.-%, more preferably in proportions of 0 to 1 cat.-%. Through its network forming properties boron cations may support the stability of the glass. In preferable embodiments the glass comprises at least 0 cat.-% of boron. Nevertheless, in the case of too high contents of boron cations in the glass the viscosity may be reduced strongly so that a reduction of the crystallization stability has to be accepted. Therefore, it is particularly preferable that the content of boron cations is at most 10 cat.-%, further preferable at most 5 cat.-%, still more preferable at most 2 cat.-%, and most preferable at most 1 cat.-%. In preferable embodiments, the glass is free of boron cations.

In the glass, preferably the sum of silicon and boron cations cat.-% is from 40 to 95, more preferably from 45 to 60 cat.-%. In preferable embodiments, the sum of silicon and boron cations cat.-% in the glass is at least 41 cat.-%, more preferably at least 42 cat.-%, still more preferably at least 43.5 cat.-%, and most preferably at least 45 cat.-%. It is particularly preferable that the sum of silicon and boron cations cat.-% in the glass is at most 75 cat.-%, further preferable at most 70 cat.-%, still more preferable at most 65 cat.-%, and most preferable at most 60 cat.-%.

It has been found that the temperature dependence of refractive index is influenced by the network formers aluminum, silicon and boron in the glass. Therefore, the glass preferably shows a ratio of the sum of aluminum and boron relative to the amount of silicon in cationic percentages of from 0 to 1. Preferably, this ratio is from >0 to 0.8, more preferably from >0.20 to 0.6, most preferably from 0.25 to 0.4.

In the glass preferably aluminum cations are contained in proportions of 0 to 20 cat.-%, more preferably 14 to 20 cat.-%. The addition of aluminum cations results in improved glass forming properties and generally supports the improvement of chemical resistance. In preferable embodiments the glass comprises at least 1 cat.-% of aluminum, more preferably at least 5 cat.-% of aluminum, still more preferably at least 10 cat.-% of aluminum, and most preferably at least 14 cat.-% of aluminum. However, too high contents of aluminum cations result in an increased tendency to crystallization. Therefore, it is particularly preferable that the content of aluminum cations is at most 20 cat.-%, further preferable at most 19 cat.-%, still more preferable at most 18 cat.-%, and most preferable at most 17 cat.-%.

The glass preferably contains fluxing agents to improve melting properties, particularly comprising alkali metal cations and/or alkaline earth metal cations. Preferably, the sum of fluxing agents Σ{ΣR²⁺ (R=Mg, Ca, Sr, Ba)+ΣR⁺ (R′=Li, Na, K)} is 5 to 40 cat.-%. In preferable embodiments the sum of the amounts of the fluxing agents in the glass is at least 5 cat.-%, more preferably at least 7 cat.-%, still more preferably at least 12 cat.-%, and most preferably at least 15 cat.-%. If the amount of fluxing agents in the glass is too high, chemical resistance will decrease. It is particularly preferable that the sum of the fluxing agents in the glass is at most 38 cat.-%, further preferable at most 35 cat.-%, still more preferable at most 33 cat.-%, and most preferable at most 30 cat.-%.

Alkali metal cations improve the meltability of the glass and thus allow for a more economic production. Also, they may be necessary for chemical strengthening of the glass by ion exchange treatment. During the production of the glass the alkali metal cations serve as fluxing agents. The sum of the amounts of the alkali metal cations lithium, sodium and potassium in the glass may be 0 to 35 cat.-%. In preferable embodiments the sum of the alkali metal cations is at least 5 cat.-%, more preferably at least 7 cat.-%, still more preferably at least 10 cat.-%, and most preferably at least 15 cat.-%. However, if contents of alkali metal cations are too high the weathering resistance of the glass may be compromised and thus the range of applications thereof may strongly be limited. Too high contents of alkali metal cations lead to a decrease in chemical stability because these monovalent ions may compromise the bridging Si—O bonds and in addition easier move in the glass structure than other cations. Therefore, it is particularly preferable that the sum of the alkali metal cations is at most 35 cat.-%, further preferable at most 30 cat.-%, still more preferable at most 27 cat.-%, and most preferable at most 25 cat.-%.

The present inventors surprisingly found that chemical stability can be further increased when the molar ratio of the sum of alkali metal cations (Li, Na, K) to the sum of boron and aluminum cations is kept in an advantageous range. Preferably, the ratio of the sum of alkali metal cations (Li, Na, K) to the sum of boron and aluminum cations in the glass is kept in a range of from 0.1 to 2.5. More preferably, the content of the sum of alkali metal cations (Li, Na, K) to the sum of boron and aluminum cations in the glass is at least 0.2, more preferably at least 0.3, more preferably at least 0.5, more preferably at least 0.8. Preferably, the content of the sum of alkali metal cations (Li, Na, K) to the sum of boron and aluminum cations in the glass is at most 2.5, more preferably at most 2.2, more preferably at most 2.0, more preferably at most 1.9, more preferably at most 1.7, more preferably at most 1.5. In this way, a glass with very high chemical stability can be obtained.

In the glass preferably lithium cations are contained in proportions of 0 to 18 cat.-%. Lithium serves as a fluxing agent and has excellent properties for ion exchange strengthening. However, lithium affects chemical stability of the glass to a great extent so that its content should be limited. It is particularly preferable that the content of lithium cations is at most 18 cat.-%, further preferable at most 10 cat.-%, still more preferable at most 3 cat.-%, and most preferable at most 1 cat.-%. In preferable embodiments the glass is free of lithium cations.

In the glass preferably sodium cations are contained in proportions of 0 to 25 cat.-%, preferably 15 to 25 cat.-%. Sodium is a good component for ion exchange treatment. But—as with all alkali metal ions—the amount of this component should not be too high because it decreases chemical stability. In preferable embodiments the glass comprises at least 5 cat.-% of sodium, more preferably at least 10 cat.-% of sodium, still more preferably at least 12 cat.-% of sodium, and most preferably at least 15 cat.-% of sodium. It is particularly preferable that the content of sodium cations is at most 24 cat.-%, further preferable at most 23 cat.-%, still more preferable at most 22 cat.-%, and most preferable at most 21 cat.-%.

In the glass preferably potassium cations are contained in proportions of 0 to 15 cat.-%, more preferably 1.5 to 8.5 cat.-%. The negative impact of potassium on chemical stability is less strong compared to the other alkali metal ions. However, potassium is not suitable for ion exchange treatment. Also, the content of potassium is preferably limited because it contains isotopes that emit beta rays. In preferable embodiments the glass comprises at least 1 cat.-% of potassium, more preferably at least 2 cat.-% of potassium, still more preferably at least 3 cat.-% of potassium, and most preferably at least 3.5 cat.-% of potassium. It is particularly preferable that the content of potassium cations is at most 15 cat.-%, further preferable at most 10 cat.-%, still more preferable at most 5 cat.-%.

It has been found that the leaching tendency of the substrate glass can be reduced by using both sodium and potassium in the glass and keeping the ratio of sodium to potassium in cat.-% in a range of up to 15, more preferably up to 10, more preferably up to 9, preferably up to 8 and most preferably less than 6. Keeping this ratio low, i.e. the sodium does not exceed a certain amount relative to the amount of potassium, provides for glass having good meltability and excellent chemical and hydrolytic resistance. Specifically, such glass will have an HGB1 according to ISO 719:1989. However, in order to adjust the viscosity in the melt to a desirable value, the ratio of sodium to potassium should be more than 0.5, preferably more than 1 and most preferably at least 2.

Alkaline earth metal cations may improve the meltability of the glass and thus allow for an economic production. During the production of the glass they may serve as fluxing agents. The sum of the alkaline earth metal cations magnesium, barium and calcium in the glass preferably is of 0 to 15 cat.-%, more preferably 2 to 9 cat.-%. Alkaline earth metal ions affect chemical resistance of the glass with little positive effects in terms of ion exchange treatment. Hence, in this invention the glass does preferably not comprise any alkali earth metal ions. It is particularly preferable that the sum of the alkali earth metal cations in the glass is at most 13 cat.-%, further preferable at most 12 cat.-%, still more preferable at most 10 cat.-%, and most preferable at most 9 cat.-%. Moreover, alkaline earth metal cations and zinc cations may be used to adjust the viscosity of the glass, particularly the fine tuning of the viscosity-temperature profile. Moreover, alkaline earth metal cations and zinc cations—like alkali metal cations—may be used as fluxing agents. The glass may be free of at least one cation selected from the group comprising magnesium cations, calcium cations, strontium cations, barium cations and zinc cations. Preferably, the glasses are free of zinc cations, calcium cations, strontium cations and barium cations.

In the glass preferably zinc cations are contained in proportions of 0 to 7 cat.-%. It is particularly preferable that the content of zinc cations is at most 6 cat.-%, more preferably at most 5 cat.-%. In preferable embodiments the glass is free of zinc. In the glass preferably calcium cations are contained in proportions of 0 to 9 cat.-%. It is particularly preferable that the content of calcium cations is at most 8 cat.-%, further preferable at most 3 cat.-%. In preferable embodiments the glass is free of calcium. In the glass preferably barium cations are contained in proportions of 0 to 4 cat.-%. It is particularly preferable that the content of barium cations is at most 4 cat.-%, further preferable at most 3 cat.-%, still more preferable at most 2 cat.-%, and most preferable at most 1 cat.-%. In preferable embodiments the glass is free of barium. In preferable embodiments the glass is free of strontium.

In the glass preferably magnesium cations are contained in proportions of 0 to 10 cat.-%, more preferably 2 to 9 cat.-%. Magnesium cations may be contained in the glass as an additional fluxing agent as well as for adjusting the melting point in a targeted manner. By the addition of the network modifier magnesium the melting point of glass may be reduced. In preferable embodiments the glass comprises at least 1 cat.-% of magnesium, more preferably at least 2 cat.-% of magnesium, still more preferably at least 3 cat.-% of magnesium. However, too high contents of magnesium cations may result in a reduction of the melting point of the glass. It is particularly preferable that the content of zinc cations is at most 8 cat.-%, further preferable at most 6 cat.-%. In the glass preferably titanium cations are contained in proportions of 0 to 5 cat.-%. Titanium cations may be added to the glass for improving its optical properties. In particular, with the help of additions of titanium the refractive index of the glass can be adjusted in a targeted manner. So the refractive index increases with an increasing content of titanium cations in the glass. The addition of titanium cations is connected with a further advantage: by this measure the UV edge of the transmittance spectrum of the glass may be shifted to higher wave lengths, wherein this shift is higher, when more titanium is added. However, too high contents of titanium cations may result in undesirable crystallization of the glass. Titanium cations may increase the refractive index of the glass. Particularly together with zirconium cations, titanium cations may deteriorate transmission in the blue spectral range and, thus may shift the UV-edge into the longer wave lengths. Therefore, it is particularly preferable that the content of titanium is at most 5 cat.-%, further preferable at most 1 cat.-%. In preferable embodiments the glass is free of titanium.

In the glass preferably zirconium cations are contained in proportions of 0 to 3 cat.-%, more preferably 0.1 to 1.3 cat.-%. Zirconium cations may be used to adjust the refractive index of the glasses. In preferable embodiments the glass comprises at least 0.1 cat.-% of zirconium, more preferably at least 0.2 cat.-% of zirconium, still more preferably at least 0.5 cat.-% of zirconium. However, a content of zirconium cations, which is too high, may decrease the meltability and particularly may lead to stronger crystallization of the glass. It is particularly preferable that the content of zirconium is at most 1.3 cat.-%, further preferable at most 1.0 cat.-%, still more preferable at most 0.8 cat.-%.

In the glass preferably cerium cations are contained in proportions of 0.01 to 0.3 cat.-%. In preferable embodiments the glass comprises at least 0.01 cat.-% of cerium, more preferably at least 0.02 cat.-% of cerium, still more preferably at least 0.05 cat.-% of cerium. It is particularly preferable that the content of cerium is at most 0.3 cat.-%, further preferable at most 0.2 cat.-%, still more preferable at most 0.1 cat.-%.

### Glass Composition II

Another preferred glass composition that may constitute the inorganic material comprises the following components, in cat.-%, based on the total molar amount of cations in the glass: silicon 48 to 60 cat.-%, boron 10.5 to 15.5 cat.-%, aluminum 2 to 8.5 cat.-%, sodium 8 to 14 cat.-%, potassium 5.5 to 13.5 cat.-%, zinc 2 to 6, titanium 1 to 5 cat.-%. In preferred embodiments, the cations in the glass consist of the cations mentioned in the before-mentioned list to an extent of at least 95%, more preferably at least 97%, most preferably at least 99%. In most preferred embodiments, the cationic components of the glass essentially consist of the mentioned cations.

Preferably, the glass comprises silicon in proportions of 40 to 75 cat.-%. Silicon is an important network former in the glass matrix which is important for the glass properties. In particular, silicon cations are important for the chemical resistance, hardness and scratch resistance of the glass. In preferable embodiments the glasses comprise at least 43 cat.-% of silicon, more preferably at least 45 cat.-% of silicon, still more preferably at least 47.5 cat.-% of silicon, and most preferably at least 48 cat.-% of silicon. However, too high contents of silicon cations result in an increase of the glass transition temperature, making glass production uneconomical. Therefore, it is particularly preferable that the content of silicon cations is at most 75 cat.-%, further preferable at most 70 cat.-%, still more preferable at most 65 cat.-%, and most preferable at most 60 cat.-%.

Besides silicon cations the glass may also comprise at least one second network former. The glass may contain boron cations as an additional network former in proportions of 0 to 23 cat.-%. Through its network forming properties boron cations may support the stability of the glass. In preferable embodiments the glass comprises at least 0 cat.-% of boron, more preferably at least 5 cat.-% of boron, still more preferably at least 7.5 cat.-% of boron, and most preferably at least 10.5 cat.-% of boron. Nevertheless, in the case of contents of boron cations in the glass which are too high the viscosity may be reduced strongly so that a reduction of the crystallization stability has to be accepted. Therefore, it is particularly preferable that the content of boron cations is at most 23 cat.-%, further preferable at most 20 cat.-%, still more preferable at most 18 cat.-%, and most preferable at most 15.5 cat.-%.

In the glass the sum of silicon and boron cations may be from 40 to 95 cat.-%. In preferable embodiments the sum of silicon and boron cations cat.-% in the glass is at least 45 cat.-%, more preferably at least 48 cat.-%, still more preferably at least 50 cat.-%, and most preferably at least 60 cat.-%. It is particularly preferable that the sum of silicon and boron cations cat.-% in the glass is at most 95 cat.-%, further preferable at most 85 cat.-%, still more preferable at most 75.0 cat.-%, and most preferable at most 72 cat.-%.

It has been found that the temperature dependence of refractive index is influenced by the network formers aluminum, silicon and boron in the glass. Therefore, the glass may have a ratio of the sum of aluminum and boron relative to the amount of silicon in cationic percentages of from 0 to 1. Preferably, this ratio is from >0 to 0.8, more preferably from >0.20 to 0.6, most preferably from 0.25 to 0.4.

In the glass aluminum cations may be contained in proportions of 0 to 20 cat.-%. The addition of aluminum cations results in improved glass forming properties and generally supports the improvement of chemical resistance. In embodiments the glass comprises at least 0 cat.-% of aluminum, more preferably at least 1 cat.-% of aluminum, still more preferably at least 2 cat.-% of aluminum, and most preferably at least 3 cat.-% of aluminum. However, contents of aluminum cations which are too high result in an increased tendency to crystallization. Therefore, it is particularly preferable that the content of aluminum cations is at most 20 cat.-%, further preferable at most 15 cat.-%, still more preferable at most 10 cat.-%, and most preferable at most 8 cat.-%.

The glass may contain fluxing agents to improve melting properties, particularly comprising alkali metal cations and/or alkaline earth metal cations. Preferably, the sum of fluxing agents Σ{ΣR²⁺ (R=Mg, Ca, Sr, Ba)+ΣR⁺ (R′=Li, Na, K)} is 5 to 40 cat.-%. In preferable embodiments the sum of the amounts of the fluxing agents in the glass is at least 5 cat.-%, more preferably at least 7 cat.-%, still more preferably at least 12 cat.-%, and most preferably at least 15 cat.-%. If the amount of fluxing agents in the glass is too high, chemical resistance will decrease. It is particularly preferable that the sum of the fluxing agents in the glass is at most 35 cat.-%, further preferable at most 30 cat.-%, still more preferable at most 25 cat.-%, and most preferable at most 23 cat.-%.

Alkali metal cations improve the meltability of the glass and thus allow for a more economic production. Also, they may be necessary for allowing chemical strengthening of the glass by ion exchange treatment. During the production of the glass the alkali metal cations serve as fluxing agents. The sum of the amounts of the alkali metal cations lithium, sodium and potassium in the glass may be 0 to 35 cat.-%. In preferable embodiments the sum of the alkali metal cations is at least 5 cat.-%, more preferably at least 7 cat.-%, still more preferably at least 10 cat.-%, and most preferably at least 15 cat.-%. However, if contents of alkali metal cations are too high the weathering resistance of the glass may be compromised and thus the range of applications thereof may be limited. Too high contents of alkali metal cations lead to a decrease in chemical stability because these monovalent ions may compromise the bridging Si—O bonds and in addition easier move in the glass structure than other cations. Therefore, it is particularly preferable that the sum of the alkali metal cations is at most 35 cat.-%, further preferable at most 30 cat.-%, still more preferable at most 25 cat.-%, and most preferable at most 23 cat.-%.

The present inventors surprisingly found that chemical stability can be further increased when the molar ratio of the sum of alkali metal cations (Li, Na, K) to the sum of boron and aluminum cations is kept in an advantageous range. Preferably, the ratio of the sum of alkali metal cations (Li, Na, K) to the sum of boron and aluminum cations in the glass is kept in a range of from 0.1 to 2. More preferably, the content of the sum of alkali metal cations (Li, Na, K) to the sum of boron and aluminum cations in the glass is at least 0.2, more preferably at least 0.3, more preferably at least 0.5, more preferably at least 0.8. Preferably, the content of the sum of alkali metal cations (Li, Na, K) to the sum of boron and aluminum cations in the glass is at most 1.9, more preferably at most 1.8, more preferably at most 1.7, more preferably at most 1.5, more preferably at most 1.3, more preferably at most 1.2. In this way, a glass with very high chemical stability can be obtained.

In the glass lithium cations may be contained in proportions of 0 to 18 cat.-%. Lithium serves as a fluxing agent and has excellent properties for ion exchange strengthening. However, lithium affects chemical stability of the glass to a great extent so that its content should be limited. It is particularly preferable that the content of lithium cations is at most 18 cat.-%, further preferable at most 10 cat.-%, still more preferable at most 3 cat.-%, and most preferable at most 1 cat.-%. In embodiments the glass is free of lithium cations.

In the glass sodium cations may be contained in proportions of 0 to 25 cat.-%. Sodium is a good component for ion exchange treatment. But—as with all alkali metal ions—the amount of this component should not be too high because it decreases chemical stability. In preferable embodiments the glass comprises at least 3 cat.-% of sodium, more preferably at least 5 cat.-% of sodium, still more preferably at least 8 cat.-% of sodium, and most preferably at least 9 cat.-% of sodium. It is particularly preferable that the content of sodium cations is at most 23 cat.-%, further preferable at most 22 cat.-%, still more preferable at most 20 cat.-%, and most preferable at most 15 cat.-%.

In the glass potassium cations may be contained in proportions of 0 to 15 cat.-%. The negative impact of potassium on chemical stability is less strong compared to the other alkali metal ions. However, potassium is not suitable for ion exchange treatment. Also, the content of potassium is preferably limited because it contains isotopes that emit beta rays. In preferable embodiments the glass comprises at least 1 cat.-% of potassium, more preferably at least 2 cat.-% of potassium, still more preferably at least 3 cat.-% of potassium, and most preferably at least 5.5 cat.-% of potassium. It is particularly preferable that the content of potassium cations is at most 15 cat.-%, further preferable at most 13 cat.-%, still more preferable at most 12 cat.-%.

It has been found that the leaching tendency of the glass can be reduced by using both sodium and potassium in the glass and keeping the ratio of sodium to potassium in cat.-% in a range of up to 5, more preferably up to 4.5, more preferably up to 3.5, preferably up to 2.0 and most preferably less than 1.6. Keeping this ratio low, i.e. the sodium does not exceed a certain amount relative to the amount of potassium, provides for glass having good meltability and excellent chemical and hydrolytic resistance. Specifically, such glass may have an HGB1 according to ISO 719:1989. However, in order to adjust the viscosity in the melt to a desirable value, the ratio of sodium to potassium should be more than 0.5, preferably more than 0.7 and most preferably at least 0.8.

Alkaline earth metal cations improve the meltability of the glass and thus allow for a more economic production. During the production of the glass they serve as fluxing agents. The sum of the alkaline earth metal cations magnesium, barium and calcium in the glass may be 0 to 15 cat.-%. Alkaline earth metal ions affect chemical resistance of the glass with little positive effects in terms of ion exchange treatment. Hence, in this invention the glass may be free of alkali earth metal ions. It is particularly preferable that the sum of the alkali earth metal cations in the glasses is at most 13 cat.-%, further preferable at most 10 cat.-%, still more preferable at most 5 cat.-%, and most preferable at most 1 cat.-%. Moreover, alkaline earth metal cations and zinc cations may be used to adjust the viscosity of the glass, particularly for the fine tuning of the viscosity-temperature profile. Moreover, alkaline earth metal cations and zinc cations—like alkali metal cations—may be used as fluxing agents. The glass may be free of at least one cation selected from the group comprising magnesium cations, calcium cations, strontium cations, barium cations and zinc cations. Preferably, the glass is free of magnesium cations, calcium cations, strontium cations and barium cations.

In the glass magnesium cations may be contained in proportions of 0 to 10 cat.-%. It is particularly preferable that the content of magnesium cations is at most 8 cat.-%, more preferably at most 6 cat.-%. In preferable embodiments, the glass is free of magnesium. In the glass calcium cations may be contained in proportions of 0 to 9 cat.-%. It is particularly preferable that the content of calcium cations is at most 8 cat.-%, further preferable at most 3 cat.-%. In preferable embodiments, the glass is free of calcium. In the glass barium cations may be contained in proportions of 0 to 4 cat.-%. It is particularly preferable that the content of barium cations is at most 4 cat.-%, further preferable at most 3 cat.-%, still more preferable at most 2 cat.-%, and most preferable at most 1 cat.-%. In preferable embodiments the glass is free of barium. In preferable embodiments, the glass is free of strontium.

In the glass zinc cations may be contained in proportions of 0 to 7 cat.-%. Zinc cations may be contained in the glass as an additional fluxing agent as well as for adjusting the melting point in a targeted manner. By the addition of the network modifier zinc the melting point of glass may be reduced. In preferable embodiments the glass comprises at least 1 cat.-% of zinc, more preferably at least 2 cat.-% of zinc, still more preferably at least 3 cat.-% of zinc. However, contents of zinc cations which are too high may result in a reduction of the melting point of the glass. It is particularly preferable that the content of zinc cations is at most 6 cat.-%, further preferable at most 5 cat.-%.

In the glass titanium cations may be contained in proportions of 0 to 5 cat.-%. Titanium cations may be added to the glass for improving their optical properties. In particular, with the help of additions of titanium the refractive index of the glass can be adjusted in a targeted manner. So the refractive index increases with an increasing content of titanium cations of the glass. The addition of titanium cations is connected with a further advantage: by this measure the UV edge of the transmittance spectrum of the glass is shifted to higher wave lengths, wherein this shift is higher, when more titanium is added. In preferable embodiments the glass comprises at least 0.1 cat.-% of titanium, more preferably at least 0.5 cat.-% of titanium, still more preferably at least 1 cat.-% of titanium, and most preferably at least 2 cat.-% of titanium. However, contents of titanium cations which are too high may result in undesirable crystallization of the glass. Titanium cations may increase the refractive index of the glass. Particularly together with zirconium cations, titanium cations may deteriorate transmission in the blue spectral range and, thus may shift the UV-edge into the longer wave lengths. Therefore, it is particularly preferable that the content of titanium is at most 5 cat.-%, further preferable at most 4 cat.-%.

It has been surprisingly found by the present inventors that hydrolytic resistance, acid resistance and alkaline resistance can be further increased when the molar ratio of zinc cations to titanium cations is kept in an advantageous range. Preferably, the molar ratio of zinc cations to titanium cations in the glass is at most 5, more preferably at most 4, more preferably at most 3. More preferably, the molar ratio of zinc cations to titanium cations in the glass is in a range of between 0.1 and 3.0. More preferably, the molar ratio of zinc cations to titanium cations in the glass is at least 0.5, more preferably at least 0.8, more preferably at least 1.0, more preferably at least 1.2. Preferably, the molar ratio of zinc cations to titanium cations in the glass is at most, 2.5, more preferably at most 2.2, more preferably at most 2.0, more preferably at most 1.7, more preferably at most 1.6.

In the glass zirconium cations may be contained in proportions of 0 to 3 cat.-%. Zirconium cations may be used to adjust the refractory index of the glass. However, a content of zirconium cations, which is too high, may decrease the meltability and particularly may lead to stronger crystallization of the glass. It is particularly preferable that the content of zirconium is at most 2 cat.-%, further preferable at most 1 cat.-%, still more preferable at most 0.5 cat.-%. In preferable embodiments the glass is free of zirconium.

### Shape and Size

The inorganic material layer preferably has a thickness of less than or equal to 400 μm, preferably less than or equal to 330 μm, also preferably less than or equal to 250 μm, further preferably less than or equal to 210 μm, preferably less than or equal to 180 μm, also preferably less than or equal to 150 μm, more preferably less than or equal to 130 μm, more preferably less than or equal to 100 μm, more preferably less than or equal to 80 μm, more preferably less than or equal to 70 μm, further preferably less than or equal to 50 μm, further preferably less than or equal to 30 μm, even preferably less than or equal to 10 μm. The thickness can be at least 5 μm. Such particularly thin layers are desired for various applications as described above. In particular, the thin thickness imparts flexibility on the layer.

According to an advantageous embodiment the inorganic material layer, such as a glass layer, can be a flat layer and/or flexible layer and/or deformable layer. A “flat” layer can for example be an essentially plane or planar layer. However, “flat” in the sense of the inventions also includes articles deformable or deformed in two or three dimensions. It is preferred that the inorganic material layer has a substantially uniform thickness. The inorganic material layer may have a total thickness variation (TTV) of not more than 10 μm, or less than 5 μm or less than 1 μm. In preferred embodiments, at least the first inorganic material layer fulfils this TTV requirement. In an embodiment at least one additional inorganic material layer does not fulfil this embodiment but includes areas of reduced thickness therein. This provides for an increased flexibility in the additional inorganic material layer while having excellent surface characteristics in the first inorganic material layer.

As mentioned before, the inorganic material layer is preferably very thin. Inorganic materials, particularly materials that have a certain brittleness, have a tendency to break upon stresses. In order to reduce the tendency of the inorganic material layer to break this invention provides measures that can be applied to the inorganic material layer. Generally, the inorganic material layer has two parallel primary surfaces on opposing sides and an edge portion connecting the two primary surfaces. In order to reduce the probability of breakage at least a part of the edge portion comprises a convex curvature so that at least one of the primary surfaces merges into the part of the edge portion. The part of the edge portion may have a curvature with an arc length, which is at least 1/30, at least 1/20, or at least 1/10 of the thickness of the inorganic material layer. The part of the edge portion may comprise indentations in the form of grooves in the area of the convex curvature. The length of the grooves may be greater than their widths and/or depths. By means of a plurality of grooves on the edge portion, any cracks that are present or formed on the surface of the edge portion influence each other so that the intensity of tension at the tips of the cracks decreases so that overall stability of the layer increases. Hence, forming a curvature as described above on the edge portion of an inorganic material layer will increase stability of the protective cover during bending or folding.

The depth of the grooves may be at least 10 nm and up to 5 μm, preferably up to 2 μm, or up to 1 μm. The grooves may be made by using an abrasive tool with a respective grain size of the abrasive medium. The part of the edge portion that has convex curvature can be attributed a curvature radius, which is the radius of a circle fitted to the beginning, middle and end point of the arc of the curvature. According to a preferred embodiment, this radius is at least 1/40, at least 1/30, or at least 1/20 of the thickness of the inorganic material layer. For the stability of the inorganic material layer even greater radii are useful. Thus, the radius of the fitted circle may be at least 1/10, or ⅕, or even half the thickness of the inorganic material layer. In other embodiments, the radius of the fitted circle may be larger than the thickness of the inorganic material layer.

In certain embodiments, the part of the edge portion may be adjacent to an area of a primary surface of the inorganic material layer. Where the part of the edge portion and area of primary surface are adjacent to each other the curvature radius may be smaller. In embodiments, the angle between tangents of the part of the edge portion and an area of the primary surface adjacent thereto may be up to 45°, up to 20°, or up to 10°. By means of this smaller radius and edge line is formed, where the slope of adjacent surfaces changes very quickly.

In order to reduce crack propagation in the inorganic material layer it is preferred that the grooves are oriented in different directions, such as obliquely and/or perpendicularly to each other. Grooves may cross each other.

### Adhesion Layer

The protective cover of this disclosure comprises an inorganic material layer and an adhesion layer. The adhesion layer may serve to fix the protective cover to a display of an electronic device, or to promote adhesion of the protective cover to other parts of the display and/or to other layers of the protective cover, such as an additional inorganic material layer, or one or more polymer layers. In the case of a removable protective cover, before use the adhesion layer may be covered by a cover sheet. The cover sheet may be peeled off before attaching the protective cover to the display of an electronic device. The cover sheet may be made from a polymeric material, such as a plastic material.

The adhesion layer may be located directly on the inorganic material layer. In certain embodiments, a further layer, or further layers may be disposed between adhesion layer and inorganic material layer, such as a polymer layer as described below and/or an additional adhesive layer between polymer layer and inorganic layer, such as an OCA (optically clear adhesives) layer and/or silicone layer. In other words, in an embodiment, the protective cover comprises the following sequence of layers: inorganic material layer, additional adhesive layer, polymer layer, adhesion layer. The adhesion layer may comprise or consist of a single layer, or a multi-layer adhesive. The adhesive strength of the protective cover on a display, such as a polyimide display, of an electronic device is preferably in the range of from 0.01 N/25 mm to 0.3 N/25 mm, preferably from 0.03 N/25 mm to 0.29 N/25 mm, more preferred from 0.05 N/25 mm to 0.26 N/25 mm.

The protective cover may be fixed to a display of an electronic device by means of the adhesion layer, wherein the adhesion layer fixes the inorganic material layer to the display of the electronic device either directly or with at least one intermediate polymer layer. Where necessary, an adhesion promoter or bonding agent may be used on the inorganic material and/or the display in order to secure the bonding of the inorganic material with the display, or of the inorganic material to other layers of the protective cover, such as a polymer layer and/or an additional inorganic material layer. Adhesion promoters suitable for that purpose are, for example, silicones or OCA, substituted silanes or hexamethyldisilazane but also epoxide coatings may be used.

When selecting the adhesion promotor as well as the adhesives and polymers for the optional polymer layer it has to be assured that they do not decrease the transmission of light too much. Further, they preferably should possess a refractive index similar to that of the glass. As the glass will be bent throughout its lifetime it is essential that the polymers affixed to it have a very low tendency to crazing and stress whitening.

The adhesion layer may comprise or consist of adhesives, such as adhesive polymers. The adhesives are preferably chosen from OCA, acrylates, methacrylates, polystyrenes, silicones and epoxides. They may be of the pressure-sensitive type, reactive type, or hot melt type. A pressure sensitive type has the advantage that the protective cover may easily be replaced in case of a damage while the other types provide a more reliable bond. In an embodiment, the adhesion layer provides adhesion between layers of the protective cover, and/or structural stability to the protective cover. Many polymers disclosed herein are able to provide these and other functions, such as those polymers disclosed herein as polymers of the polymer layer.

The adhesion layer preferably has a thickness, which is less than the thickness of the inorganic material layer. In case of a polymer layer present in the protective cover, the adhesion layer is preferably thinner than the polymer layer as well. The thickness of the adhesion layer is preferably in a range of less than 100 μm, less than 80 μm, less than 60 μm, less than 40 μm, or less than 20 μm, or even less than 10 μm. The adhesion layer may be coated, printed, or laminated to the inorganic material layer or the polymer layer. The adhesion layer may essentially completely cover the inorganic material layer or the polymer layer, i.e. the adhesion layer may cover the surface of the inorganic material layer or the polymer layer to an extent of at least 50%, at least 60%, at least 70%, at least 80%, at least 90%, at least 95%, or at least 99%.

### Polymer Layer

The protective cover of the present disclosure can comprise a polymer layer between inorganic material layer and adhesion layer. In an embodiment, the protective cover comprises the inorganic material layer, polymer layer and adhesion layer in exactly this sequence without any further layers in between. In an embodiment, there may be a further layer between inorganic material layer and polymer layer comprising a bonding agent that facilitates bonding between the polymer of the polymer layer and the inorganic material of the inorganic material layer.

Generally, the polymer of the polymer layer should have good compatibility with the inorganic material and the adhesion layer. In preferred embodiments, the water drop contact angle of the polymer of the polymer layer differs to the water drop contact angle of the inorganic material by less than 30°, less than 20°, less than 10°. The contact angle can be measured by using a commercial contact angle testing machine.

The polymer intermediate layer will predominantly serve two purposes. On the one hand it will provide the comparatively fragile inorganic layer with a mechanical reinforcement. And on the other hand it will function as a security means by immobilizing the splinters and particles in case of a fracture of the inorganic layer. Hence, a very good adhesion to the inorganic material, i.e. high peeling forces, is required as well as a good tear propagation resistance and puncture resistance. Nevertheless, the adhesion layer should allow that the protective cover is peeled off again from the display of the electronic device, e.g. in case of breakage of the inorganic material. The polymers of the polymer layer are preferably selected from polystyrene (PS), poly(ethylene terephthalate) (PET), ethylene glycol modified poly(ethylene terephthalate) (PETG), poly(ethylene-vinyl acetate) (EVA), polycarbonate (PC), polyimide (PI), polyvinyl chloride (PVC), polyvinyl butyral (PVB), thermoplastic polyurethanes (TPU), or poly(methyl methacrylate) (PMMA), more preferably from polyvinyl butyral (PVB), thermoplastic polyurethanes (TPU), ethylene glycol modified poly(ethylene terephthalate) (PETG), poly(ethylene-vinyl acetate) (EVA), polycarbonate (PC), polyethylene (PE), epoxy resin, or combinations thereof.

The polymer layer can be laminated onto the inorganic material layer. In another embodiment, the polymer layer can be coated onto the inorganic material layer. The polymer layer may essentially completely cover the inorganic material layer, i.e. the polymer layer covers the surface of the inorganic material layer to an extent of at least 50%, at least 60%, at least 70%, at least 80%, at least 90%, at least 95%, or at least 99%, optionally with one or more additional layers in between.

According to an advantageous embodiment, the polymer layer has a thickness of at least 1 μm, preferably of at least 5 μm, further preferably of at least 10 μm, more preferably of at least 20 μm, most preferably of at least 40 μm to reach the desired resistance. An upper limit for the thickness of polymer layer could be 250 μm, 200 μm, 150 μm or 100 μm.

The polymer layer can be laminated onto the inorganic material layer, or it may be printed or coated. Lamination can be performed by different known methods. In addition, or as an alternative to the above-mentioned polymers, the polymer material for the polymer layer can be selected for example from the group consisting of a silicone polymer, a sol-gel polymer, polycarbonate (PC), polyethersulphone, polyacrylate, polyimide (PI), an inorganic silica/polymer hybrid, a cycloolefin copolymer, a polyolefin, a silicone resin, polyethylene (PE), polypropylene, polypropylenepolyvinyl chloride, polystyrene, styrene-acrylonitrile copolymer, thermoplastic polyurethane resin (TPU), polymethyl methacrylate (PMMA), ethylene-vinyl acetate copolymer, polyethylene terephthalate (PET), polybutylene terephthalate, polyamide (PA), polyacetal, polyphenyleneoxide, polyphenylenesulfide, fluorinated polymer, a chlorinated polymer, ethylene-tetrafluoroethylene (ETFE), polytetrafluoroethylene (PTFE), polyvinyl chloride (PVC), polyvinylidene chloride (PVDC), polyvinylidene fluoride (PVDF), polyethylene naphthalate (PEN), a terpolymer made of tetrafluroethylene, a terpolymer made of hexafluoropropylene, and a terpolymer made of vinylidene fluoride (THV) or polyurethane, or mixtures thereof. The polymer layer can be applied onto the inorganic material layer by any known method.

According to an embodiment, the polymer layer is coated onto the inorganic material layer. The coating of a protective layer can be applied by any known coating method such as chemical vapor deposition method (CVD), dip-coating, spin-coating, ink-jet, casting, screen printing, painting and spraying. However, the invention is not limited to those procedures. Suitable coating materials are also known in the art. For example they can comprise a duroplastic reaction resin that is a polymer selected from the group consisting of phenoplasts, phenol formaldehyde resins, aminoplasts, urea formaldehyde resins, melamine formaldehyde resins, epoxide resins, unsaturated polyester resins, vinyl ester resins, phenacrylate resins, diallyl phthalate resins, silicone resins, cross-linking polyurethane resins, polymethacrylate reaction resins, and polyacrylate reaction resins.

### Additional Inorganic Material Layers

The protective cover can comprise at least one additional inorganic material layer, such as a second inorganic material layer. This additional layer may impart more mechanical strength to the protective cover. In an embodiment, the layer consists of glass in accordance with the above-described glass composition I or II.

In one embodiment, the additional inorganic material layer consists of an alkali-containing glass, such as alkali aluminosilicate glass, alkali silicate glass, alkali borosilicate glass, alkali alum inoborosilicate glass, alkali boron glass, alkali germanate glass, alkali borogermanate glass, alkali soda lime glass, and combinations thereof. The additional inorganic material layer is bendable or even foldable. Generally, the outer layers of a protective cover are subject to tensile stresses due to bending or folding, or impact stresses.

The thickness of the additional inorganic material layer may be less than 700 μm, less than 500 μm, less than 300 μm, less than 250 μm, less than 200 μm, less than 150 μm, less than 100 μm, less than 75 μm, less than 70 μm, less than 50 μm, less than 30 μm, or less than 15 μm. The thicker the layer is, the higher is the mechanical stability. The thinner the layer is, the higher is its ability to bend and fold.

The additional inorganic material layer may have a Vickers hardness HV_{0.2/25} of from 400 to 800 MPa. A toughened additional inorganic material layer may have a Vickers hardness HV_{0.2/25} of from 450 to 1000 MPa. An untoughened additional inorganic material layer may have a Knoop hardness HK_{0.1/20} of from 350 to 750 MPa. A toughened additional inorganic material layer may have a Knoop hardness HK_{0.1/20} of from 400 to 800 MPa.

In certain embodiments, the additional inorganic material layer may have a thickness of less than 0.175 mm, less than 0.145 mm, less than 0.1 mm, less than 0.07 mm, or even less than 0.05 mm.

For the material of the additional inorganic material layer the same properties may be desired as for the first inorganic material layer described, such as bending strength, alkali leaching factor, and acid leaching factor.

In an embodiment, the protective cover comprises an adhesion layer and/or a polymer layer disposed between a first and a second inorganic material layer.

In an embodiment, the protective cover comprises a first inorganic material layer and a second inorganic material with a polymer layer disposed between the two inorganic material layers. Adhesion layers may further be disposed between polymer layer and each of the inorganic material layers. The adhesion layer disposed between the first inorganic material layer and the polymer layer may be an OCA layer. The adhesion layer disposed between the second inorganic material layer and the polymer layer may be a silicone layer.

The first inorganic material layer can be very thin, such as from 10 to 150 μm, or from 25 to 100 μm, or from 30 to 70 μm, or about 50 μm. This first inorganic material layer may be chemically toughened. Due to its very low thickness, this layer may have very high flexibility including the ability to bend and/or fold.

The second inorganic material layer may be thicker than the first inorganic material layer. It may have a thickness ranging from 50 μm to 300 μm, or from 75 μm to 200 μm, or from 90 μm to 150 μm. The second inorganic layer is sufficiently flexible, but also provides the protective cover with mechanical strength. In an embodiment, the second inorganic material layer is part of an infoldable protective cover, i.e. the second inorganic material layer is on the side of the protective cover that is being stretched, when the cover is folded. Thicker glass is very sensitive to compression and less sensitive to stretching. Thereby, it is possible to exploit the mechanical strength of the second inorganic material layer and to benefit from the first inorganic material layer's very low thickness.

In an embodiment first and second inorganic material layers may be laminated using one or more adhesion layers and/or polymer layers. The first inorganic material layer may have a thickness of about 50 μm, and the second inorganic material layer may have a thickness of about 100 μm. In another embodiment, the protective cover has exactly one inorganic material layer which may be thicker than the first inorganic material layer in a protective cover with more than one inorganic material layer; in this embodiment the inorganic material layer may have a thickness of more than 100 μm, or more than 120 μm.

The adhesion layer can comprise or consist of a polymer, such as one of the polymers mentioned above for the adhesion layer and/or for the polymer layer. The polymer layer may comprise or consist of a polymer, such as one of the polymers mentioned above for the polymer layer. The adhesion and/or polymer layer may be very thin such as less than 100 μm, or less than 70 μm, or less than 50 μm, or less than 30 μm, or less than 15 μm or even less than 5 μm. This layer is useful to securely attach the first inorganic material layer to the second inorganic material layer. Polymers in the adhesion layer may provide the layer with sufficient flexibility to enable the protective cover to bend and fold. A second adhesion layer may be disposed on the other side of the second inorganic material layer so as to facilitate attachment of the protective cover to the display and/or the electronic device.

In order to increase the ability of the first and/or second inorganic material layer to bend and fold the layer may comprise one or more areas of reduced thickness. One or more areas of reduced thickness may be arranged at or in the vicinity of a bending axis. The bending axis extends at the surface of the inorganic material layer, where the tensile stress peaks during bending. The bending axis may be located inside the protective cover, e.g. extending in a width direction on the surface of an inorganic material layer. In an embodiment the areas of reduced thickness may have an elongated shape, i.e. a length which is much greater than a width of the area, such as one or more grooves, gaps or furrows in the inorganic material. The areas of reduced thickness may be cut or ground into the material. The areas of reduced thickness may be oriented in a direction which is substantially parallel to the bending axis and/or substantially perpendicular to the longitudinal axis of the protective cover. The areas of reduced thickness may be present on the side that faces towards the display and/or the electronic device so as to provide for the best effect on bendability and/or foldability of an infoldable protective cover. In an embodiment, the areas of reduced thickness may be arranged on side of the inorganic material layer that faces away from an interface of the first inorganic material layer and the surrounding air.

The first and/or second inorganic material layer can have a plurality of areas of reduced thickness in the form of grooves, furrows or gaps oriented substantially parallel to the bending axis of the respective layer. A plurality may include at least 2, at least 4, at least 6, at least 10, at least 15 or at least 20 areas of reduced thickness. In an embodiment, the grooves, gaps or furrows have a very small width, such as a maximum width of less than 1 mm, or less than 100 μm, or less than 10 μm, or less than 1 μm, or less than 0.4 μm, or less than 0.2 μm. Very thin areas of reduced thickness may be almost invisible to the user of the protective cover. The areas of reduced thickness, such as the grooves, gaps or furrows may extend over a portion of at least 40% of the width of the respective inorganic material layer, or at least 60%, or at least 80% or at least 90% of the layer. In an embodiment, one or more or all of the gaps, furrows or grooves extend over the whole width of the respective layer. In the case of gaps, this will result in a segmentation of the first and/or second inorganic material layer, wherein the different segments form elongated bars of inorganic material separated by the gaps. This may provide excellent flexibility and bendability. A polymer and/or adhesion layer may keep the bars in place.

This invention includes embodiments of protective covers that have exactly one inorganic material layer. In these embodiments, one or more areas of reduced thickness as described herein may be present in the one inorganic material layer. In embodiments with only one inorganic material layer the one layer may be thicker than in protective covers with more than one inorganic material layer, such as more than 100 μm, or more than 120 μm.

In an embodiment, the first and/or second inorganic material layer have an area of reduced thickness that is characterized by a continuous reduction of thickness of the second inorganic material in the direction of the bending axis, wherein at the bending axis the smallest thickness may be achieved. Thereby, the bendability is highest at the bending axis where bending is required. The highest thickness may be at a portion of the second inorganic material layer that is farthest from the bending axis. Thickness reduction may be achieved e.g. by polishing, scoring, cutting (e.g. laser cutting), grinding and/or by etching. Optionally, any grinding and/or cutting may be followed by etching the resulting grooves, furrows, cracks and/or indentations. Etching is suitable to smoothen any cracks or sharp edges so as to make the layer less susceptible to damages.

In another embodiment, the protective cover has a single inorganic layer having a relatively larger thickness, such as from 100 μm to 300 μm, or from 150 μm to 250 μm, or from 175 μm to 225 μm. The first inorganic layer may have an improved bendability by incorporation of areas of reduced thickness as described above. Areas of reduced thickness and improved bendability may include areas having a thickness of less than 100 μm, such as less than 70 μm, such as less than 50 μm, or less than 30 μm. These areas may extend over a central part of the inorganic material layer that corresponds to the area of the bending axis. The area may for example cover from 1% to 10% of the inorganic material layer and/or the protective cover.

Generally, areas of reduced thickness may lead to breakage of an inorganic material layer. This may be an intended effect, if the inorganic material layer or the parts of the inorganic material layer obtained after breakage are securely attached by the adhesion layer and/or polymer layer so that they remain in place after breakage. An embodiment that causes an inorganic material layer to break upon first bending has the advantage that the protective cover will have almost unlimited flexibility. In this context, it would be useful to have a very thin and straight area of reduced thickness where the inorganic material layer may break so as to produce only a very thin and straight gap in the material after breakage in order not to produce a cover that appears broken. This can be achieved e.g. by scoring.

In the case of grooves, or furrows the areas of reduced thickness may be cut into the inorganic material layer by scoring. An advantageous way of scoring the areas of reduced thickness is described in US 2017/0217817 A1, which is incorporated in this document by reference as if fully set forth herein. Additionally or alternatively, scoring may be done using the scoring method as described in US 2016/0185647 A1, which is incorporated in this document by reference as if fully set forth herein. Additionally or alternatively, scoring may be done using the scoring method as described in US 2016/0152506 A1, which is incorporated in this document by reference as if fully set forth herein. The scoring methods are particularly useful to produce areas of reduced thickness that lead to breakage of the inorganic material layer upon first bending. In embodiments in may be desired to provoke breakage along the scoring line before first bending the protective cover. In this case the scoring lines can be forced to break by adding a liquid, such as an alcohol into the scoring lines and heating to cause the inorganic material to break along the scoring lines. This method leads to very thin gaps that are essentially invisible with the naked eye.

In an embodiment, the areas of reduced thickness are gaps in the inorganic material. These gaps can be formed by scoring the inorganic material, and forming a gap in the inorganic material along the scoring lines, e.g. using a liquid as described above. Also, gaps may be formed using laser cutting as mentioned above. The areas of reduced thickness may be partially or completely filled with a material of similar refractive index n_{d}, such as a material having a refractive index that differs from the refractive index of the inorganic material by not more than 0.3, or not more than 0.2, or not more than 0.1. Keeping the refractive index in that range will improve the optical appearance of the protective cover. Suitable materials may be selected from the materials mentioned above for the polymer and/or adhesion layer.

### Production of Protective Cover

The present disclosure also provides a method of making a protective cover according to this invention, comprising the steps:
providing an inorganic material layer,
attaching an adhesion layer on the inorganic material layer.

Attaching the adhesion layer to the inorganic material layer may include coating the inorganic material layer with an adhesion layer. Where the protective cover comprises a polymer layer, the adhesion layer may be attached to the polymer layer, or coated to the polymer layer. Where the protective cover comprises any additional inorganic material layer, the adhesion layer may be attached to the additional inorganic material layer, or coated to the additional inorganic material layer. The polymer layer may be coated to the first and/or any additional inorganic material layer, or it may be laminated to the inorganic material layer. The polymer layer may be attached or coated to the inorganic material layer directly or indirectly. An intermediate layer such as an additional adhesive layer, e.g. an OCA layer, may be attached or coated to the inorganic layer and/or the polymer layer. Any known coating method may be used for coating such as chemical vapor deposition method (CVD), dip-coating, spin-coating, ink-jet, casting, screen printing, painting and spraying.

A preferred method includes the step of providing one or more inorganic material layers by selecting inorganic material layers on the basis of desired parameters given herein, such as those measured according to the sandpaper press test and/or the sandpaper ball drop test discussed above.

Preferably, the inorganic material layer or layers in the protective cover of the invention can be glass layers, such as an ultrathin glass (UTG) layer. Such layer could be produced by polishing down from thicker glass. However, this method is not economical and leads to bad surface quality which is quantified by Rₐ roughness for example.

Direct hot-forming production like down draw or overflow fusion method are preferred for the mass production. The redraw method is also advantageous. These mentioned methods are economical and the glass surface quality is high and glass with thickness from 5 μm (or even less) to 500 μm could be produced. For example, the down-draw/overflow fusion method make pristine or fire-polished surfaces with roughness Rₐ less than 5 nm, less than 2 nm, or less than 1 nm. The thickness could also be precisely controlled ranging from 5 μm and 500 μm. The thin thickness grants the glass flexibility. The special float process could produce glass with pristine surfaces, it is economical and suitable for mass production too, but the glass produced by floating has one tin-side which is different from the other side. The difference between two sides would cause warp of glass after chemical toughening, and affect any printing or coating process because the two sides have different surface energy. Another variant of glass layers can be produced by sawing glass articles out of a thick glass ingot, bar, block and the like.

Optional strengthening, also called toughening, can be done by immersing glass into a molten salt bath with potassium ions or cover the glass with a paste containing potassium ions or other alkaline metal ions and heat it to high temperatures for a certain time. The alkaline metal ions with larger ion radius in the salt bath or the paste exchange with alkaline metal ions with smaller radius in the glass layer, and surface compressive stress is formed due to ion exchange.

A chemically toughened glass layer that can be used as an inorganic material layer is obtained by chemically toughening a chemically toughenable glass layer. The toughening process may be done by immersing the glass layer into a salt bath which contains monovalent ions to exchange with alkali ions inside the glass. The monovalent ions in the salt bath have radii larger than alkali ions inside glass. A compressive stress to the glass is built up after ion-exchange due to larger ions squeezing in the glass network. After the ion-exchange, the strength and flexibility of glass are surprisingly and significantly improved. In addition, the CS induced by chemical toughening improves the bending properties of the toughened glass layer and could increase scratch resistance of glass.

The most frequently used salt bath for chemical toughening is Na⁺-containing or K⁺-containing molten salt or a mixture thereof. Commonly used salts are NaNO₃, KNO₃, NaCl, KCl, K₂SO₄, Na₂SO₄, Na₂CO₃, and K₂CO₃. Additives like NaOH, KOH and other sodium salt or potassium salt may be used for better controlling the speed of ion-exchange, CS and DoL during chemical toughening. Ag⁺-containing or Cu²⁺-containing salt bath could be used to add anti-microbial function to the glass.

The chemical toughening is not limited to a single step. It can include multi steps in one or more salt baths with alkaline metal ions of various concentrations to reach better toughening performance. Thus, the chemically toughened glass layer can be toughened in one step or in the course of several steps, e.g. two steps.

A chemically toughened glass layer may have just one surface (first surface) where a compressive stress region extending from the first surface to a first depth in the glass layer exists, wherein the region is defined by a compressive stress. In this case the glass layer comprises only one toughened side, which in the case of the protective cover of the invention may be the side facing away from the adhesion layer. Preferably the glass layer may comprise a second compressive stress region extending from the second surface to a second depth in the glass layer (DoL), the region is defined by a compressive stress wherein the surface compressive stress (CS) at the second surface is at least 100 MPa. The second surface is located opposite to the first surface. Thus, this preferred glass layer is toughened on both sides.

Compressive stress (CS) mostly depends on the composition of glass. Higher content Al₂O₃ can be helpful to achieve higher compressive stress. To reach balanced glass hot-forming capabilities and chemical toughening performance, the surface compressive stress is preferably below 1200 MPa. After toughening, the glass should have high enough compressive stress to achieve high strength. Therefore, preferably surface compressive stress at the first surface and/or at the second surface is equal to or more than 100 MPa, preferably equal to or more than 200 MPa, more preferably equal to or more than 300 MPa, also preferably equal to or more than 400 MPa, further preferably equal to or more than 500 MPa. In especially preferred embodiments, surface compressive stress is equal to or more than 600 MPa, further preferably equal to or more than 700 MPa, more preferably equal to or more than 800 MPa. Of course the CS at the first surface and the CS at the second surface can be essentially the same or can be different.

Generally, DoL depends on glass composition, but it can increase nearly infinitely with increased toughening time and toughening temperature. A defined DoL is important to ensure the stable strength of toughened glass, but too high DoL increases the self-breakage ratio and the strength performance when the inorganic material layer is under compressive stress.

So according to a variant of the present disclosure, DoL may be controlled to be quite low (low DoL variant). To achieve the defined low DoL the toughening temperature and/or the toughening time is/are reduced. According to the present disclosure, a lower toughening temperature may be preferred as DoL is more sensitive to the temperature and a longer toughening time is easily to be set during mass production. However, a reduced toughening time is also possible in order to decrease DoL of the glass layer.

The present inventors have found that it will be advantageous for the stress profile of the glass layer if the glass layer has a DoL (in μm) in a range of 0.5 μm to 150*t/CS μm (t given in μm, CS=figure of surface compressive stress (given in MPa)) measured at a first surface). Preferably the glass layer has a DoL (in μm) in a range of 0.5 μm to 120*t/CS μm, preferred 1 μm to 120*t/CS μm (t given in μm, CS=figure of surface compressive stress (given in MPa) measured at a first surface)), further preferably a DoL (in μm) in a range of 0.5 μm to 90*t/CS μm, preferred 1 μm to 90*t/CS μm (t given in μm, CS=figure of surface compressive stress (given in MPa)) measured at a first surface). Some advantageous embodiments may have a DoL (in μm) in a range of 0.5 μm to 60*t/CS μm, preferred 1 μm to 60*t/CS μm (t given in μm, CS=figure of surface compressive stress (given in MPa) measured at a first surface)). Other advantageous embodiments may have a DoL (in μm) in a range of 0.5 μm to 45*t/CS μm, preferred 1 μm to 45*t/CS μm (t given in μm, CS=figure of surface compressive stress (given in MPa) measured at a first surface)). Other advantageous embodiments may have a DoL (in μm) in a range of 0.5 μm to 27*t/CS μm, preferred 1 μm to 27*t/CS μm (t given in μm, CS=figure of surface compressive stress (given in MPa) measured at a first surface)). In the above given calculations “x*t/CS” means that x is multiplied by the thickness of the glass layer and divided by the figure of the measured surface CS wherein x can be 150, 120, 90, 60, 45, or 27.

The advantageous value of DoL depends in each case on the glass composition, the thickness and applied CS of the respective glass layer. In general, glass layers according to the above mentioned advantageous embodiments have a quite low DoL. By decreasing the DoL, the CT decreases. If high press force is applied on such embodiments by sharp objects, the caused defects will just be on the glass surface. Since the CT is reduced significantly the caused defect is not able to overcome the internal strength of the glass layer, and thus the glass layer does not break into two or several pieces. Such a glass layer with low DoL has an improved sharp press resistance.

According to another variant of the present disclosure, the DoL of the glass layer may be quite high (high DoL variant). It can be advantageous if the glass layer has a DoL (in μm) in a range of 27*t/CS μm to 0.5*t μm (t given in μm, CS=figure of surface compressive stress (given in MPa) measured at a first surface), preferably a DoL (in μm) in a range of 45*t/CS μm to 0.45*t μm (t given in μm, CS=figure of surface compressive stress (given in MPa) measured at a first surface), more preferably a DoL (in μm) in a range of 60*t/CS μm to 0.4*t μm (t given in μm, CS=figure of surface compressive stress (given in MPa) measured at a first surface), more preferably a DoL (in μm) in a range of 90*t/CS μm to 0.35*t μm (t given in μm, CS=figure of surface compressive stress (given in MPa) measured at a first surface). In the above given calculations “y*t/CS” means that y is multiplied by the thickness of the glass layer and divided by the figure of the measured surface CS wherein y can be 27, 45, 60, or 90. “z*t” means that z is multiplied by the thickness of the glass layer wherein z can be 0.5, 0.45, 0.4, or 0.35. In order to achieve a balanced stress profile such glass layer may comprise a coated and/or laminated layer. The coated layer and/or laminated layer can resist defects of scratches induced on the glass surface by sharp objects even if the DoL of the glass layer is quite high. Thus, the inventors have found that alternative to lowering DoL, depositing a coating and/or laminating a polymer layer on one or both surfaces of the glass layer can be applied in order to increase the sharp contact resistance. Of course a glass layer having a low DoL can comprise a coated layer and/or laminated layer too.

According to an advantageous embodiment of the present disclosure, the toughened glass layer has a CT of less than or equal to 200 MPa, more preferably less than or equal to 150 MPa, more preferably less than or equal to 120 MPa, more preferably less than or equal to 100 MPa. Some advantageous embodiments can have a CT of less than or equal to 65 MPa. Other advantageous embodiments can have a CT of less than or equal to 45 MPa. Some variants may even have a CT of less than or equal to 25 MPa. These CT values are especially advantageous for glass layers belonging to the low DoL variant.

Because of the low DoL those glass layers have a decreased internal CT. Decreased CT highly influences the press resistance of the toughened glass layer. Even if sharp and hard objects damage the toughened surface of a glass layer having a quite low CT the layer does not break as the internal strength of the glass structure cannot be overcome by the low CT.

Alternatively, it may be advantageous for glass layers belonging to a high DoL variant if they have a central tensile stress (CT) of more than or equal to 27 MPa, further preferably more than or equal to 45 MPa, further preferably more than or equal to 65 MPa, further preferably more than or equal to 100 MPa.

As mentioned above CS, DoL and CT depends on the glass composition (glass type), glass thickness and toughening conditions.

The areas of reduced thickness may be rim-treated. The rims of the areas of reduced thickness are where the reduced thickness area meets the surface of the inorganic material layer. Rim-treatment may include etching so that rounded rims are obtained. These rounded rims improve stability of the inorganic material and may avoid breakage in case a rim touches the opposing side of the inorganic material layer during bending.

The area of reduced thickness may extend over the whole width of the respective inorganic material layer parallel to the bending axis, thereby providing excellent flexibility and/or bendability. The area of reduced thickness may have an extension in a direction perpendicular to the bending axis and parallel to the surface of the inorganic material layer of at least π*r, wherein r is the breakage bending radius of the inorganic material layer without the area of reduced thickness, e.g. prior to etching an area of reduced thickness.

The inorganic material layer has a maximum thickness reduction, where it has the smallest thickness, and a half-maximum thickness reduction, where the thickness of the inorganic material layer is reduced to an extent of 50% relative to the maximum thickness reduction present in the same inorganic material layer. In an embodiment, the minimum distance between an area of maximum thickness reduction and half-maximum thickness reduction within one area of reduced thickness is at least π*r/2, wherein r is the breakage bending radius of the inorganic material layer without the area of reduced thickness. Such an article will have excellent bendability and/or foldability because the area of reduced thickness takes into account the bending behavior of the inorganic material layer. In embodiments of this invention, the maximum thickness reduction is where bending of the inorganic material layer occurs, i.e. at the bending axis. In embodiments with more than one inorganic material layer the maximum thickness reduction may amount to 100% of the original thickness of the layer, i.e. it may form a gap in the inorganic material layer.

Generally, the maximum thickness reduction may be up to 90%, or up to 80%, or up to 60% of the original thickness of the respective layer. Generally, the maximum thickness reduction may be at least 10%, or at least 30%, or at least 40% of the original thickness of the respective layer.

Preferably, the maximum thickness reduction is where the maximum tensile stress occurs during bending. The areas of reduced thickness will preferably be disposed on the compression surface of the inorganic material layer, while the tensile stress occurs on the opposite side (tension surface). The tensile stress on the tension surface is highest where bending takes place. Tensile stress decreases with increasing distance from the bending axis. Preferably, the same is true for the thickness reduction. In preferred embodiments, the relative local tensile stress (in percent relative to the maximum tensile stress) at a given location on the tension surface of the inorganic material layer corresponds to the relative thickness reduction at that location (in percent relative to the maximum thickness reduction). For example, the tensile stress during bending may be highest where the tension surface is closest to the bending axis, i.e. the spot where the inorganic material layer preferably has the lowest thickness (the maximum thickness reduction). In preferred embodiments, the tensile stress at the tension surface is about 50% (i.e. 45% to 55%) of the maximum tensile stress, where the inorganic material layer has a half-maximum thickness reduction.

Preferably, the relative local thickness reduction in percent is essentially the same as the relative local tensile stress in percent at a given location on the tension surface of the inorganic material layer during bending, wherein bending includes bending the protective cover up to the breakage bending radius. In this context “essentially the same” means that the ratio of relative local tensile stress (in %) to relative local thickness reduction (in %) is from 0.8:1 to 1.2:1, preferably from 0.9:1 to 1.1:1, in particular from 0.95:1 to 1.05:1. Preferably, the relative local thickness reduction is essentially the same as the relative local tensile stress at every location on the tension surface of the inorganic material layer during bending, wherein bending includes bending the protective cover up to the breakage bending radius.

### LIST OF REFERENCE SIGNS

1 protective cover
2 inorganic material layer
3 adhesion layer
4 polymer layer
5 neutral plane
6 tension surface
7 compression surface
8 optically clear adhesive
11 steel plate
12 pen
13 area of reduced thickness

### EXAMPLES

### Example 1

A pen drop test is performed on a protective cover according to a preferred embodiment of this invention. The test was performed as described above with reference to FIG. 5. A protective cover film included 0.07 mm ultrathin alumosilicate glass as the inorganic material layer, an OCA adhesion layer, a polymer layer of PE and an adhesive layer of silicone. The total thickness of polymer layer, adhesion layer and silicone layer was 0.125 mm. The silicone side is glued on the inorganic material layer. The OCA adhesion layer is for the lamination with flexible smartphones. The average CS and DoL of the protective cover film are 650 MPa and 10 μm, respectively. A ball-point pen drop is performed. 30 pieces of the protective cover were tested and the average pen drop height was around 50 mm. In addition, a bending test is performed. 30 pieces of the protective cover were tested with a bending radius of 5 mm. All protective covers can pass 100,000 times with a bending speed of 60 times/min at the room temperature with a humidity of 30%.

### Example 2

A pen drop test is performed on a curved protective cover according to a preferred embodiment of this invention. The test was performed as described above with reference to FIG. 6.

A protective cover film included 0.07 mm ultrathin alumosilicate glass as the inorganic material layer, an OCA adhesion layer, a polymer layer of PE and an adhesive layer of silicone. The total thickness of polymer layer, adhesion layer and silicone layer was 0.125 mm. The silicone side is glued on the inorganic material layer. The OCA adhesion layer is for the lamination with flexible smartphones. The average CS and DoL of the protective cover film are 700 MPa and 8 μm, respectively. A ball-point pen drop is performed. The bending radius was 4 mm. 30 pieces of the protective cover were tested and the average pen drop height was around 60 mm.

### Example 3

A pen drop test is performed on a protective cover according to a preferred embodiment of this invention. The test was performed as described above with reference to FIG. 8. A protective cover film included 0.21 mm ultrathin alumosilicate glass as the inorganic material layer, an OCA adhesion layer, a polymer layer of PE and an adhesive layer of silicone. The central part of the ultrathin glass is etched by HF acid and the removed thickness is 0.13 mm. The total thickness of polymer layer, adhesion layer and silicone layer was 0.125 mm. The silicone side is glued on the inorganic material layer. The OCA adhesion layer is suitable for the lamination with flexible smartphones. The average CS and DoL of the protective cover film are 800 MPa and 10 μm, respectively. Therefore, the protective cover film can bend with a bending radius of 5 mm at the etched part. A ball-point pen drop is performed on the thick part. 30 pieces of the protective cover were tested and the average pen drop height was around 60 mm.

1. A protective cover, comprising:
at least one transparent inorganic material layer; and
at least one transparent adhesion layer,
wherein the coefficient of thermal expansion of the inorganic material layer is from 1 to 10 ppm/K,
wherein the thickness of the inorganic material layer is less than 250 μm,
wherein the thickness of the adhesion layer is less than 100 μm,
wherein the inorganic material layer comprises a glass or a glass ceramic, or consists of a glass or a glass ceramic,
wherein the protective cover is bendable and/or foldable and has a bending axis that is perpendicular to a longitudinal axis of the inorganic material layer, and
wherein the protective cover has a weight loss after breakage of less than 10%.

2. The protective cover according to claim 1, further comprising at least one polymer layer disposed between transparent inorganic material layer and adhesion layer, wherein the coefficient of thermal expansion of the polymer layer is from 1 to 15 ppm/K.

3. The protective cover according to claim 1, wherein the difference in refractive index nd of the inorganic material layer and the adhesion layer is less than 0.3.

4. The protective cover according to claim 2, wherein the difference in CTE between the inorganic material layer and the polymer layer, and/or between the inorganic material layer and the adhesion layer is less than 15 ppm/K.

5. The protective cover according to claim 2, wherein the thickness of the polymer layer is less than 250 μm.

6. The protective cover according to claim 1, wherein the adhesion layer comprises an adhesive selected from the group consisting of OCA, acrylates, methacrylates, polystyrenes, silicones, epoxides, and mixtures thereof.

7. The protective cover according claim 2, wherein the polymer layer comprises a polymer selected from the group consisting of polystyrene (PS), poly(ethylene terephthalate) (PET), ethylene glycol modified poly(ethylene terephthalate) (PETG), poly(ethylene-vinyl acetate) (EVA), polycarbonate (PC), polyimide (PI), polyvinyl chloride (PVC), polyvinyl butyral (PVB), thermoplastic polyurethanes (TPU), or poly(methyl methacrylate) (PMMA), silicone polymer, a sol-gel polymer, polyethersulphone, polyacrylate, an inorganic silica/polymer hybrid, a cycloolefin copolymer, a polyolefin, a silicone resin, polyethylene (PE), polypropylene, polypropylenepolyvinyl chloride, styrene-acrylonitrile copolymer, polybutylene terephthalate, polyamide (PA), polyacetal, polyphenyleneoxide, polyphenylenesulfide, fluorinated polymer, a chlorinated polymer, ethylene-tetrafluoroethylene (ETFE), polytetrafluoroethylene (PTFE), polyvinyl chloride (PVC), polyvinylidene chloride (PVDC), polyvinylidene fluoride (PVDF), polyethylene naphthalate (PEN), a terpolymer made of tetrafluroethylene, a terpolymer made of hexafluoropropylene, and a terpolymer made of vinylidene fluoride (THV) or polyurethane, and combinations thereof.

8. The protective cover according to claim 2, wherein the polymer of the polymer layer has a water drop contact angle that differs from the water drop contact angle of the inorganic material layer by less than 30°.

9. The protective cover according to claim 2, wherein the protective cover has an internal transmittance for electromagnetic radiation of more than 25% in a wavelength range of 50 nm within a spectrum of from 380 to 800 nm, when measured at a thickness of 2 mm.

10. The protective cover according to claim 1, wherein the protective cover exhibits particle sizes after breakage in the size range of from 0.1 to 10 mm.

11. The protective cover according to claim 1, wherein the protective cover is bendable and/or foldable, and wherein the protective cover withstands at least 100,000 bending and/or folding events without breakage.

12. The protective cover according to claim 1, wherein the inorganic material layer has a Vickers hardness of from 400 to 800 MPa.

13. The protective cover according to claim 1, wherein the inorganic material layer has a scratch resistance larger than 6H.

14. The protective cover according to claim 1, wherein the inorganic material layer has a pen drop height larger than 30 mm in the unbent state.

15. The protective cover according to claim 1, wherein the inorganic material layer has a ratio of the pen drop height in the bent state, when the bending radius of the inorganic material is larger than 4 mm, to the pen drop height in the unbent state of not less than 30%.

16. The protective cover according to claim 1, wherein the average bending strength of the inorganic material layer and/or the protective cover is larger than 850 MPa.

17. The protective cover according to claim 1, wherein the inorganic material of the inorganic material layer has an alkali leaching factor of at most 20 μmol/dm².

18. The protective cover according to claim 1, wherein the inorganic material of the inorganic material layer has an acid leaching factor of at most 20 μmol/dm².

19. The protective cover according to claim 1, wherein the crack initiation load of the inorganic material layer is at least 1.5 N.

20. The protective cover according to claim 1, wherein the inorganic material of the inorganic material layer comprises an alkali-containing glass.

21. The protective cover according to claim 20, wherein the alkali-containing glass is selected from the group consisting of alkali aluminosilicate glass, alkali silicate glass, alkali borosilicate glass, alkali aluminoborosilicate glass, alkali boron glass, alkali germanate glass, alkali borogermanate glass, alkali soda lime glass, and combinations thereof.

22. The protective cover according to claim 1, wherein the inorganic material of the inorganic material layer is a glass that comprises the following components, in cat.-%, based on the total molar amount of cations in the glass: silicon 40 to 75 cat.-%, boron 0 to 23 cat.-%, aluminum 0 to 20 cat.-%, lithium 0 to 18 cat.-%, sodium 0 to 25 cat.-%, potassium 0 to 15 cat.-%, magnesium 0 to 10 cat.-%, calcium 0 to 9 cat.-%, barium 0 to 4 cat.-%, zinc 0 to 7 cat.-%, titanium 0 to 5 cat.-%, zirconium 0 to 3 cat.-%.

23. The protective cover according to claim 1, wherein the cover is arranged on a display of an electronic device, or wherein the protective cover is an integral part of the display, or wherein the protective cover constitutes the display of an electronic device.

24. The protective cover according to claim 1, wherein the inorganic material layer has a total thickness variation (TTV) of not more than 10 μm.

25. The protective cover according to claim 1, wherein the inorganic material layer has a thickness of from 10 to 150 μm.
